(19) United States
(12) Patent Application Publication
(10) Pub. No.: US 2026/0292972 A1
(43) Pub. Date: Sep. 24, 2026

(54) PHOTOSENSITIVE RESIN COMPOSITION, RESIN FILM HAVING PATTERN, METHOD FOR PRODUCING RESIN FILM HAVING PATTERN, AND SEMICONDUCTOR CIRCUIT BOARD

(71) Applicant: JSR CORPORATION, Tokyo (JP)

(72) Inventors: Taku OGAWA, Minato-ku, Tokyo (JP); Shin-ya NAKAFUJI, Minato-ku, Tokyo (JP); Mitsuka ANDO, Minato-ku, Tokyo (JP); Kimiyuki KANNO, Minato-ku, Tokyo (JP); Ryoji TATARA, Minato-ku, Tokyo (JP); Hirokazu ITO, Minato-ku, Tokyo (JP)

(73) Assignee: JSR CORPORATION, Tokyo (JP)

(21) Appl. No.: 18/874,134

(22) PCT Filed: Apr. 10, 2023
(86) PCT No.: PCT/JP2023/014565

§ 371 Date: Dec. 12, 2024

(30) Foreign Application Priority Data
Jun. 14, 2022 (JP) 2022-096000

(51) Int. Cl. H05K 1/02; G03F 7/038; G03F 7/32; H05K 1/03; H05K 3/00

(52) U.S. Cl. CPC H05K 1/0256; G03F 7/0387; G03F 7/325; H05K 1/0306; H05K 3/0023; H05K 2201/015; H05K 2201/0154; H05K 2203/1194

(57) ABSTRACT

A photosensitive resin composition includes a polymer (A) which is at least one type selected from a group consisting of a polyimide and a polyimide precursor, includes a structural unit (a) including a structural unit derived from an acid anhydride represented by a formula (1) below and a structural unit (b) derived from a diamine, and has, for example, a maleimide group at a polymer terminal, (B) a photopolymerization initiator, and a solvent (D). L represents, for example, a single bond, R¹ to R³ represent, for example, a hydrogen atom, or an alkylene group formed by bonding R¹ and R² (or R³) in the same ring to each other, n¹ to n² represent an integer of 0 to 3, and Y¹ represents a structure represented by, for example, a formula (Y1): (—Ar¹—).

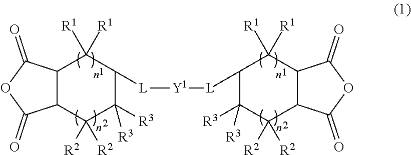

### TECHNICAL FIELD

One aspect of the present invention relates to a photosensitive resin composition, a resin film having a pattern, a method for producing a resin film having a pattern, and a semiconductor circuit board.

### BACKGROUND ART

Conventionally, various photosensitive resin compositions have been proposed as materials used for forming, for example, a surface protective film and an interlayer insulation film used for a semiconductor circuit board in an electronic component. For example, a photosensitive resin composition including a resin having a phenolic hydroxy group as an alkali-soluble resin has been studied (Patent Literatures 1 and 2).

### CITATION LIST

### Patent Literature

Patent Literature 1: JP 2014-186300 A
Patent Literature 2: JP 2013-210606 A

### SUMMARY OF INVENTION

### Technical Problem

A package technology using a silicon interposer or a fan-out type package technology using a mold substrate, for example, has been proposed to increase a density and performance of a semiconductor circuit board. However, since a substrate material and an insulation film have different coefficients of linear thermal expansion, warpage deformation may easily occur due to, for example, a temperature change in a manufacturing process of the semiconductor circuit board or the use environment of the information terminal device. In a case where the insulation film has small elongation properties, there is a problem that the insulation film cannot withstand the warpage deformation and is thus damaged. In addition, also in an environmental load test (for example, PCT test) assuming a use environment of the information terminal device, high reliability capable of maintaining elongation properties is required.

Furthermore, the insulation film used in the semiconductor circuit board is used between fine pitch electrode pads or between wirings. Therefore, a composition for forming a resin film having a pattern such as an insulation film (hereinafter, also referred to as a “patterned resin film”) is required to have photolithographic properties capable of patterning by exposure and development.

The present invention has been made to solve the above problems, and an object of the present invention is to provide a photosensitive resin composition that is capable of forming a resin film having excellent elongation properties and high PCT resistance, and that has excellent photolithographic properties, to provide a patterned resin film that has excellent elongation properties and high PCT resistance, and a method for producing the same, and to provide a semiconductor circuit board including a patterned resin film that has excellent elongation properties and high PCT resistance.

### Solution to Problem

The present inventors have conducted intensive studies in order to solve the above problems. As a result, the present inventors have found that the above problems can be solved by a photosensitive resin composition including a polymer having a specific structural unit, and a specific photopolymerization initiator, and have completed the present invention. Examples of aspects of the present invention are shown below.

[1]

A photosensitive resin composition including:
(A) a polymer that is at least one type selected from a group consisting of a polyimide and a polyimide precursor;
(B) a photopolymerization initiator; and
(D) a solvent, in which
the polymer (A) includes a structural unit (a) derived from an acid anhydride and a structural unit (b) derived from a diamine,
the structural unit (a) includes a structural unit (a1) derived from an acid anhydride represented by a formula (1) below, and
the polymer (A) has a group represented by a formula (eg1) or (eg2) below or a maleimide group at least one of a side chain terminal and a main chain terminal.

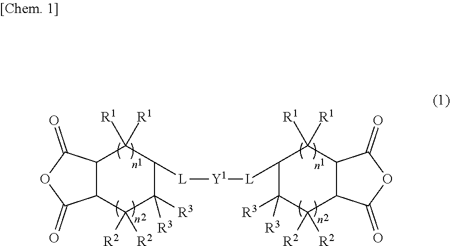

In the formula (1),
L's independently represent a single bond, an ester bond, or an amide bond,
R¹, R², and R³ each independently represent a hydrogen atom or an alkyl group having 1 to 6 carbon atoms, or an alkylene group having 1 to 4 carbon atoms formed by bonding R¹ and R² or R¹ and R³ in a same ring to each other,
n¹ and n² each independently represent an integer of 0 to 3 (provided that, in the same ring, at least one of n¹ and n² is an integer of 1 or more),
Y¹ represents a structure represented by a formula (Y1) or (Y2) below:

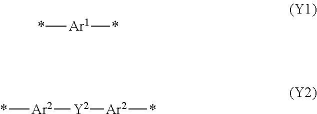

in the formulae (Y1) and (Y2), * represents a bond to L in the formula (1),
Ar¹ and Ar² each independently represent an unsubstituted aromatic ring or a group obtained by removing two hydrogen atoms on an aromatic ring from an aromatic ring substituted with an alkyl group or an alkoxy group having 1 to 6 carbon atoms, and
Y² in the formula (Y2) is at least one type of group selected from a group consisting of a single bond, an oxygen atom, a sulfur atom, a sulfonyl group, a carbonyl group, a methylene group, a dimethylmethylene group, and a bis(trifluoromethyl)methylene group.

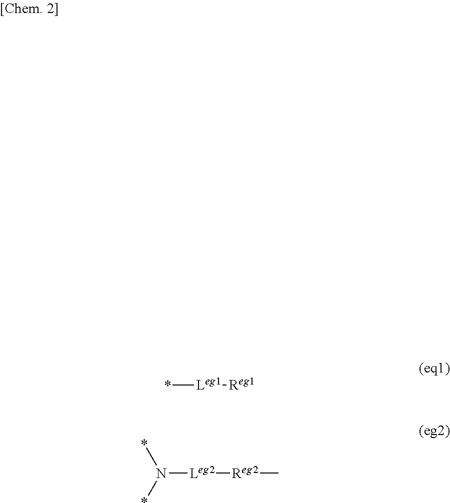

In the formulae (eg1) and (eg2),
L^{eg1} and L^{eg2} each independently represent an alkanediyl group having 1 to 5 carbon atoms, an aromatic hydrocarbon group having 6 to 10 carbon atoms, or a group in which two or more groups selected from these are linked by a single bond, —O—, —S—, —SO₂—, —NH—, —NH—C(O)—, —C(O)—, or —C(O)O—,
R^{eg1} and R^{eg2} each independently represent a vinyl group or a (meth)acryloyl group, and
* represents a binding site for a polymer chain.
   [2]

The photosensitive resin composition according to [1], further including a photopolymerizable compound (C).

[3]

The photosensitive resin composition according to [1] or [2], in which the polymer (A) has a group represented by the formula (eg1) or (eg2) or a maleimide group at least one main chain terminal.

[4] The photosensitive resin composition according to any one of [1] to [3], in which the polymer (A) is a linear polymer having no branched structure.
[5]

The photosensitive resin composition according to any one of [1] to [4], in which the polymer (A) has a group represented by formula (eg1-1) to (eg1-3), (eg2-1), or (eg3-1) at least one main chain terminal.

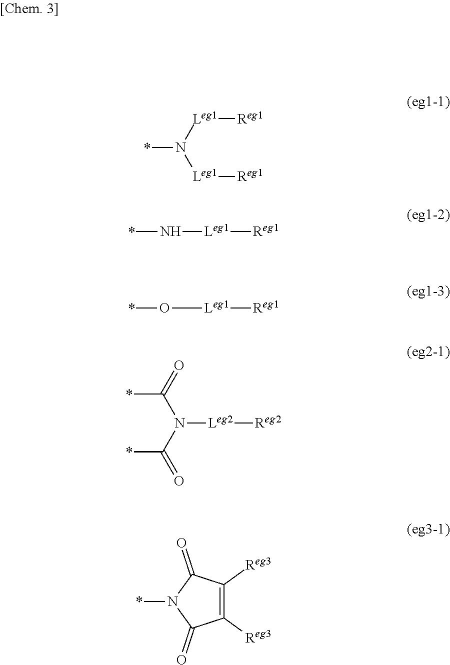

In the formulae,
L^{eg1}, R^{eg1}, L^{eg2}, and R^{eg2} have the same meanings as the same signs in the formulae (eg1) and (eg2),
R^{eg3}'s independently represent a hydrogen atom or an alkyl group having 1 to 5 carbon atoms, and R^{eg3}'s may be bonded to each other to form a ring, and
* represents a binding site for a polymer chain.
   [6]

A method for producing a resin film having a pattern, the method including: a step (1) of forming, on a substrate, a coating film of the photosensitive resin composition according to any one of [1] to [5]; a step (2) of selectively exposing the coating film; and a step (3) of developing the coating film after exposure with a developer containing an organic solvent.

[7]

A resin film having a pattern obtained by curing the photosensitive resin composition according to any one of [1] to [5].

[8]

A semiconductor circuit board including the resin film having a pattern according to [7].

### Advantageous Effects of Invention

According to an aspect of the present invention, it is possible to provide a photosensitive resin composition that is capable of forming a resin film having excellent elongation properties and high PCT resistance, and that has excellent photolithographic properties, and to provide a patterned resin film that has excellent elongation properties and high PCT resistance, and a method for producing the same, and to provide a semiconductor circuit board including a patterned resin film that has excellent elongation properties and high PCT resistance.

### DESCRIPTION OF EMBODIMENTS

Hereinafter, with respect to the present invention, embodiments for carrying out the present invention will be described in detail including preferred embodiments.

### [Photosensitive Resin Composition]

A photosensitive resin composition according to an aspect of the present invention (hereinafter also simply referred to as the “present composition”) includes:
(A) a polymer that is at least one type selected from a group consisting of a polyimide and a polyimide precursor (hereinafter also referred to as “polymer (A)”);
(B) a photopolymerization initiator; and
(D) a solvent.

### <Polymer (A)>

The polymer (A) included in the present composition is a polymer (resin) that is at least one type selected from the group consisting of a polyimide and a polyimide precursor, and includes a structural unit (a) derived from an acid anhydride and a structural unit (b) derived from a diamine, and has a specific group at least one of a side chain terminal and a main chain terminal. In particular, in the case of having this specific group at a main chain terminal, an increase in elongation rate can be expected due to an increase in molecular weight of a resin accompanying a crosslinking reaction. Since the polymer (A) contains such a structure, the polymer (A) included in the present composition can have both high i-line transmittance and high elongation rate.

### (Structural Unit (a))

The structural unit (a) includes a structural unit (a1) derived from an acid anhydride represented by the following formula (1). It is considered that the acid anhydride group having an alicyclic structure in the structural unit (a1) contributes to improvement of i-line transmittance, solvent solubility, and PCT resistance, and the aromatic group contributes to improvement of elongation rate. When the polymer (A) includes the structural unit (a1), the present composition has both high i-line transmittance and high elongation rate. As the structural unit (a1), one type or two or more types may be included.

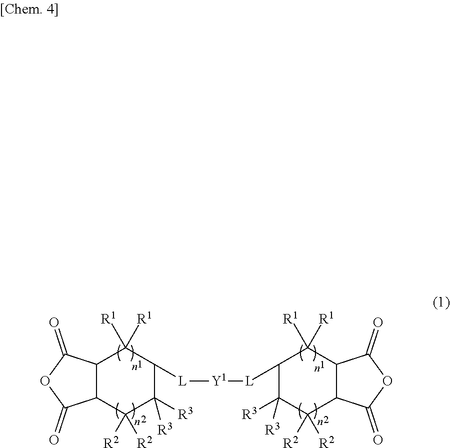

In the formula (1), Y¹ represents a structure represented by the following formula (Y1) or (Y2), and is preferably a structure represented by the following formula (Y¹). In the following formula, * represents a bond to L in the formula (1).

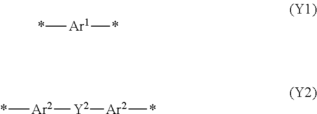

In the formulae (Y1) and (Y2), Ar¹ and Ar² each independently represent an unsubstituted aromatic ring or a group obtained by removing two hydrogen atoms on an aromatic ring from an aromatic ring substituted with an alkyl group or an alkoxy group having 1 to 6 carbon atoms.

Examples of the aromatic ring include aromatic hydrocarbon compounds such as a benzene ring and a naphthalene ring and heteroaromatic compounds such as a furan ring and a pyrrole ring, and aromatic hydrocarbon compounds having 6 to 10 carbon atoms such as a benzene ring and a naphthalene ring are preferable.

Examples of the alkyl group having 1 to 6 carbon atoms include a methyl group, an ethyl group, a n-propyl group, an isopropyl group, a n-butyl group, a n-pentyl group, and a n-hexyl group. Examples of the alkoxy group having 1 to 6 carbon atoms include a methoxy group and an ethoxy group. Among these, an alkyl group having 1 or 2 carbon atoms such as a methyl group or an ethyl group, or an alkoxy group having 1 or 2 carbon atoms such as a methoxy group or an ethoxy group is preferable.

In the formula (Y2), Y² is at least one type of group selected from the group consisting of a single bond, an oxygen atom, a sulfur atom, a sulfonyl group, a carbonyl group, a methylene group, a dimethylmethylene group, and a bis(trifluoromethyl)methylene group.

In the formula (1), L independently represents a single bond, an ester bond, or an amide bond, the ester bond includes either bond represented by —O—C(O)— or —C(O)—O—, and the amide bond includes either bond represented by —NH—C(O)— or —C(O)—NH—.

In the formula (1), R¹, R², and R³ each independently represent a hydrogen atom or an alkyl group having 1 to 6 carbon atoms, or an alkylene group having 1 to 4 carbon atoms formed by bonding R¹ and R² or R¹ and R³ in the same ring to each other. Examples of the alkyl group having 1 to 6 carbon atoms include those similar to the alkyl groups described above, and a methyl group and an ethyl group are preferable.

In the formula (1), n¹ and n² each independently represent an integer of 0 to 3, and is preferably 0 or 1. Provided that, in the same ring, at least one of n¹ and n² is an integer of 1 or more.

As the acid anhydride represented by the formula (1), R¹ to R³ in the formula (1) are preferably all hydrogen atoms, or an alkylene group having 1 or 2 carbon atoms formed by bonding one R¹ and one R² or one R¹ and one R³ in the same ring to each other. Preferable specific examples of the acid anhydride represented by the formula (1) include acid anhydrides represented by the following formulae (1-1) to (1-3), and more preferable examples thereof include an acid anhydride represented by the following formula (1-1) or (1-2).

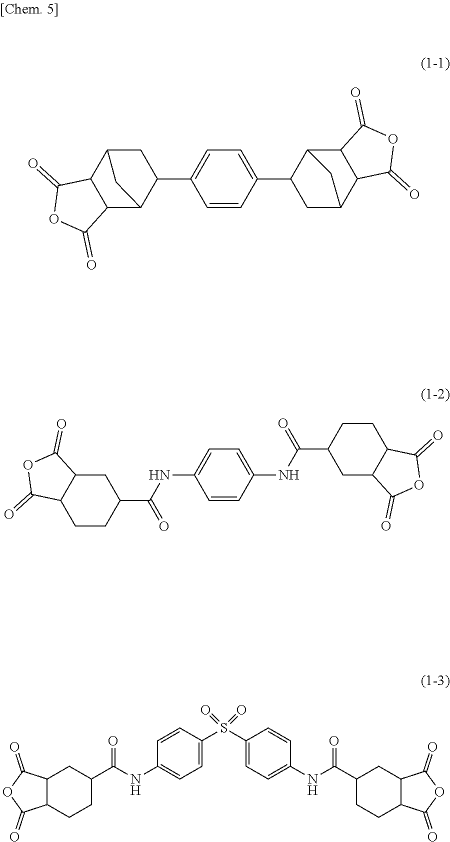 [SMILES: O=C1OC(=O)C2C3CC(CC3c3ccc(C4CC5CC4C4C(=O)OC(=O)C54)cc3)C12 ; O=C(Nc1ccc(NC(=O)C2CCC3C(=O)OC(=O)C3C2)cc1)C1CCC2C(=O)OC(=O)C2C1 ; O=C(Nc1ccc(S(=O)(=O)c2ccc(NC(=O)C3CCC4C(=O)OC(=O)C4C3)cc2)cc1)C1CCC2C(=O)OC(=O)C2C1]

The structural unit (a) may include a structural unit (a2) derived from an acid anhydride other than the acid anhydride represented by the formula (1) as long as the effect of the present invention is not impaired, and as the structural unit (a2), one type or two or more types may be included.

As the acid anhydride other than the acid anhydride represented by the formula (1) (hereinafter also referred to as “another acid anhydride”), an acid anhydride represented by the following formula (2) is preferable.

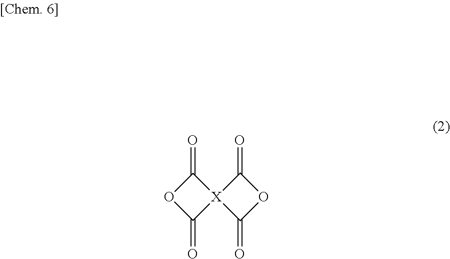

In the formula (2), examples of X include groups represented by the following formulae. In the following formulae, * represents a bond to a carbon atom to which X in the formula (2) is bonded.

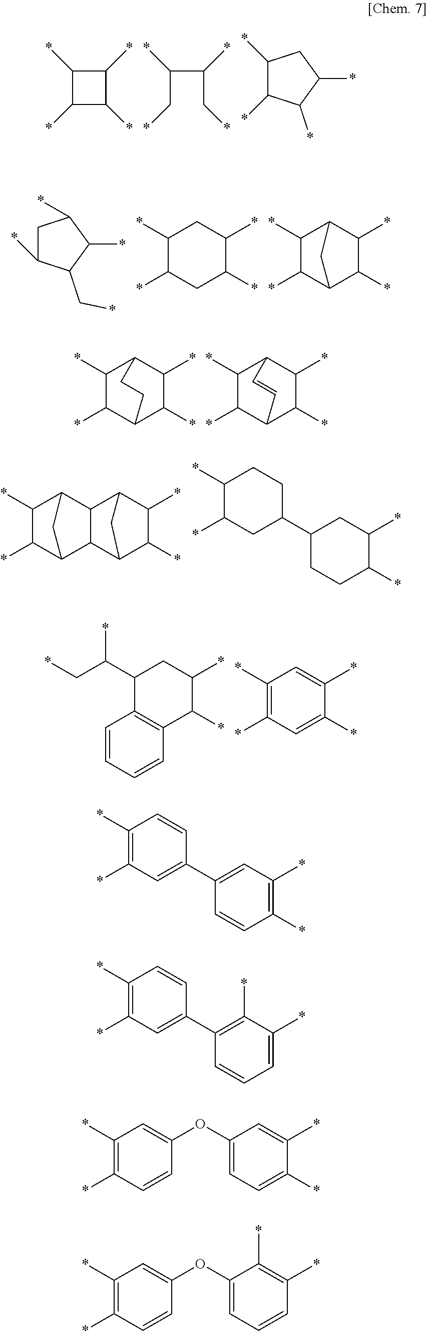

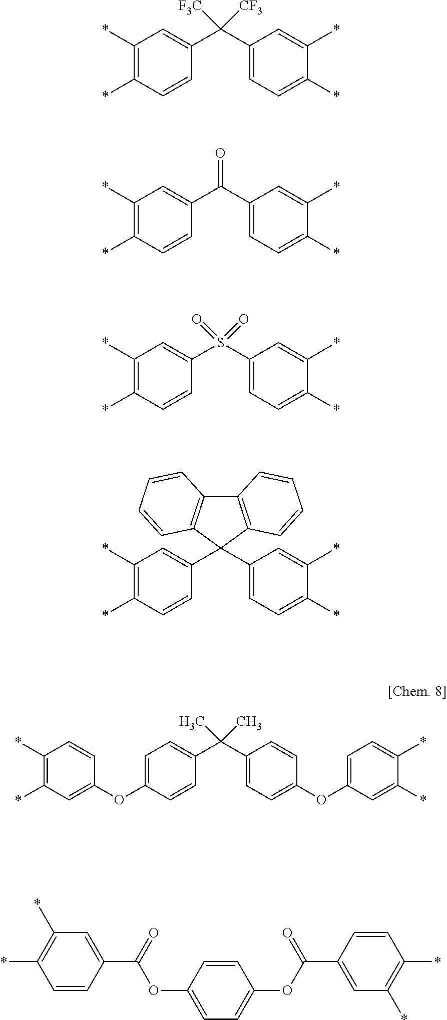 [SMILES: *c1ccc(C(c2ccc(*)c(*)c2)(C(F)(F)F)C(F)(F)F)cc1* ; *c1ccc(C(=O)c2ccc(*)c(*)c2)cc1* ; *c1ccc(S(=O)(=O)c2ccc(*)c(*)c2)cc1* ; *c1ccc(C2(c3ccc(*)c(*)c3)c3ccccc3-c3ccccc32)cc1* ; *c1ccc(Oc2ccc(C(C)(C)c3ccc(Oc4ccc(*)c(*)c4)cc3)cc2)cc1* ; *c1ccc(C(=O)Oc2ccc(OC(=O)c3ccc(*)c(*)c3)cc2)cc1*]

A hydrogen atom (omitted in the formula) in the group represented by the formula may be substituted with, for example, an alkyl group or alkoxy group having 1 to 6 carbon atoms, or a group in which a hydrogen atom in the alkyl group or alkoxy group is substituted with a halogen atom (for example, a trifluoromethyl group).

When the polymer (A) includes the structural unit (a2), the content molar ratio of the structural unit (a1) to the structural unit (a2) (structural unit (a1)/structural unit (a2)) is preferably 99/1 to 50/50, and more preferably 95/5 to 60/40. The content ratio of each structural unit can be measured by ¹³C-NMR. When the content molar ratio of the structural unit (a1) to the structural unit (a2) is within the above range, the above-mentioned effect of using the structural unit (a1) is easily obtained. The polymer in which the content molar ratio of each monomer (an acid anhydride, a diamine described later, and any other monomer component except a terminal modifier described later) in the monomer mixture is within the above range can be said to be a polymer in which the content molar ratio of the structural unit derived from each monomer is within the above range.

### (Structural Unit (b))

The structural unit (b) is not particularly limited as long as it is a structural unit derived from a diamine, and may include either a structural unit derived from a diamine having a hydroxy group or a structural unit derived from a diamine having no hydroxy group. As the structural unit (b), one type or two or more types may be included.

Examples of the diamine having a hydroxy group include a diamine represented by the following formula (3).

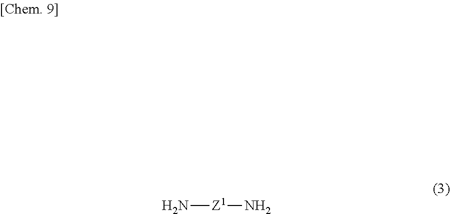

In the formula (3), Z¹ represents a divalent group having a hydroxy group, and specific examples thereof include a divalent group having a hydroxy group shown below. In the following formulae, * represents a bond to a nitrogen atom to which Z¹ in the formula (3) is bonded.

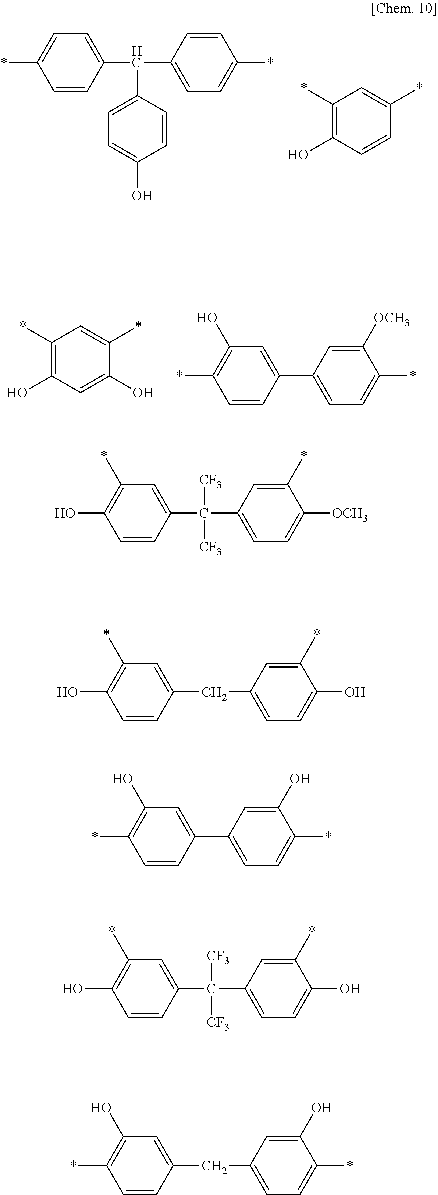

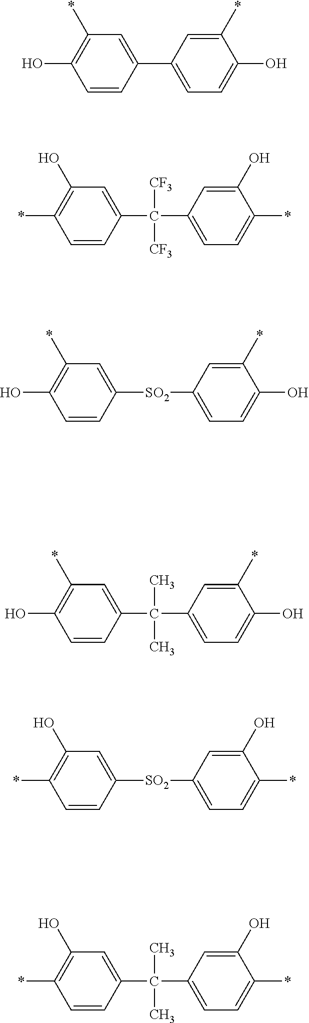 [SMILES: *c1cc(-c2ccc(O)c(*)c2)ccc1O ; *c1ccc(C(c2ccc(*)c(O)c2)(C(F)(F)F)C(F)(F)F)cc1O ; *c1cc(S(=O)(=O)c2ccc(O)c(*)c2)ccc1O ; *c1cc(C(C)(C)c2ccc(O)c(*)c2)ccc1O ; *c1ccc(S(=O)(=O)c2ccc(*)c(O)c2)cc1O ; *c1ccc(C(C)(C)c2ccc(*)c(O)c2)cc1O]

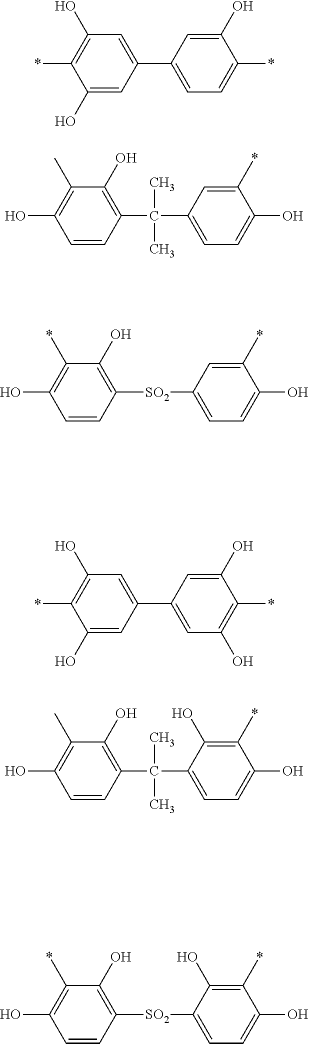

Examples of the diamine having no hydroxy group include aromatic diamines such as p-phenylenediamine, m-phenylenediamine, 4,4′-diaminodiphenylmethane, 4,4′-diaminodiphenylethane, 4,4′-diaminodiphenyl sulfide, 4,4′-diaminodiphenyl sulfone, 3,3′-dimethyl-4,4′-diaminobiphenyl, 4,4′-diaminobenzanilide, 4,4′-diaminodiphenyl ether, 1,5-diaminonaphthalene, 2,2′-dimethyl-4,4′-diaminobiphenyl, 5-amino-1-(4′-aminophenyl)-1,3,3-trimethylindane, 6-amino-1-(4′-aminophenyl)-1,3,3-trimethylindane, 3,4′-diaminodiphenyl ether, 3,3′-diaminobenzophenone, 3,4′-diaminobenzophenone, 4,4′-diaminobenzophenone, 1,3-bis(4-aminophenoxy) propane, 1,4-bis(4-aminophenoxy) butane, 1,5-bis(4-aminophenoxy) pentane, 1,6-bis(4-aminophenoxy) hexane, 2,2-bis [4-(4-aminophenoxy)phenyl]propane, 2,2-bis[4-(4-aminophenoxy)phenyl]hexafluoropropane, 2,2-bis(4-aminophenyl) hexafluoropropane, bis[4-(4-aminophenoxy)phenyl]sulfone, 1,4-bis(4-aminophenoxy)benzene, 1,3-bis(4-aminophenoxy)benzene, 1,3-bis(3-aminophenoxy)benzene, 9,9-bis(4-aminophenyl)-10-hydroanthracene, 2,7-diaminofluorene, 9,9-bis(4-aminophenyl) fluorene, 4,4′-methylene-bis(2-chloroaniline), 2,2′,5,5′-tetrachloro-4,4′-diaminobiphenyl, 2,2′-dichloro-4,4′-diamino-5,5′-dimethoxybiphenyl, 3,3′-dimethoxy-4,4′-diaminobiphenyl, 1,4,4′-(p-phenyleneisopropylidene)bisaniline, 4,4′-(m-phenyleneisopropylidene)bisaniline, 2,2′-bis[4-(4-amino-2-trifluoromethylphenoxy)phenyl]hexafluoropropane, 4,4′-bis(4-aminophenoxy) biphenyl, 4,4′-diamino-2,2′-bis(trifluoromethyl) biphenyl, and 4,4′-bis[(4-amino-2-trifluoromethyl)phenoxy]-octafluorobiphenyl; aliphatic or alicyclic diamines such as meta-xylylenediamine, para-xylylenediamine, 1,3-propanediamine, tetramethylenediamine, pentamethylenediamine, hexamethylenediamine, heptamethylenediamine, octamethylenediamine, nonamethylenediamine, decamethylenediamine, dodecamethylenediamine, 4,4′-diaminoheptamethylenediamine, 1,4-diaminocyclohexane, 1,3-bis(aminomethyl)cyclohexane, 1,4-bis(aminomethyl)cyclohexane, isophoronediamine, tetrahydrodicyclopentadienylenediamine, hexahydro-4,7-methanoindanylenedimethylenediamine, tricyclo[6.2.1.02,7]-undecylenedimethyldiamine, and 4,4′-methylenebis(cyclohexylamine); siloxane-containing diamines such as 1,3-bis(3-aminopropyl)tetramethyldisiloxane; polyether diamines; and polyoxyalkylenediamines.

The content molar ratio of the structural unit (a) to the structural unit (b) in the polymer (A) (structural unit (a)/structural unit (b)) is preferably 60/40 to 40/60, and more preferably 55/45 to 45/55. The content ratio of each structural unit can be measured by ¹³C-NMR. The polymer in which the content molar ratio of each monomer in the monomer mixture is within the above range can be said to be a polymer in which the content molar ratio of the structural unit derived from each monomer is within the above range.

### (Terminal Structure)

The polymer (A) has a group represented by the following formula (eg1) or (eg2) or a maleimide group at least one of a side chain terminal and a main chain terminal (hereinafter also collectively referred to as “polymer terminal”), preferably has a group represented by the following formula (eg1) or (eg2) or a maleimide group at least one main chain terminal, and more preferably has a group represented by the following formula (eg1) or (eg2) or a maleimide group at both main chain terminals.

When the polymer (A) has the above-mentioned group at a main chain terminal, an increase in elongation rate can be expected due to an increase in molecular weight of a resin accompanying a crosslinking reaction.

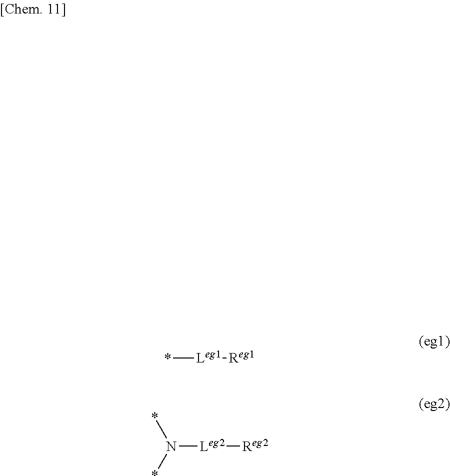

In the formulae, L^{eg1} and L^{eg2} represent an alkanediyl group having 1 to 5 carbon atoms, an aromatic hydrocarbon group having 6 to 10 carbon atoms, or a group in which two or more groups selected from these are linked by a single bond, —O—, —S—, —SO₂—, —NH—, —NH—C(O)—, —C(O)—, or —C(O)O—, and R^{eg1} and R^{eg2} represent a vinyl group or a (meth)acryloyl group. In the above formulae, * represents a binding site for a polymer chain, but the group represented by the above formula or a maleimide group may sometimes represent not only all or part of a structure (atomic group) derived from a terminal modifier described later introduced at a terminal in the polymer chain using the terminal modifier, but also may sometimes include a structure derived from a monomer that provides each of the structural units described above.

Examples of the alkanediyl group having 1 to 5 carbon atoms include a methylene group, an ethanediyl group, and a propanediyl group. Examples of the aromatic hydrocarbon group having 6 to 10 carbon atoms include groups formed of the above-mentioned aromatic hydrocarbon compounds having 6 to 10 carbon atoms.

Examples of preferred embodiments in which a group represented by the formula (eg1) or (eg2) or a maleimide group is introduced at a polymer terminal include groups represented by the following formulae (eg1-1) to (eg1-3), (eg2-1), and (eg3-1). That is, the polymer (A) preferably has a group represented by the following formula (eg1-1) to (eg1-3), (eg2-1), or (eg3-1) at a polymer terminal thereof. The groups represented by the following formulae (eg1-1) to (eg1-3) and (eg2-1) are groups in which atoms bonded to the polymer chain, which are not specified in the groups represented by the formulae (eg1) and (eg2), are further specified one atom at a time.

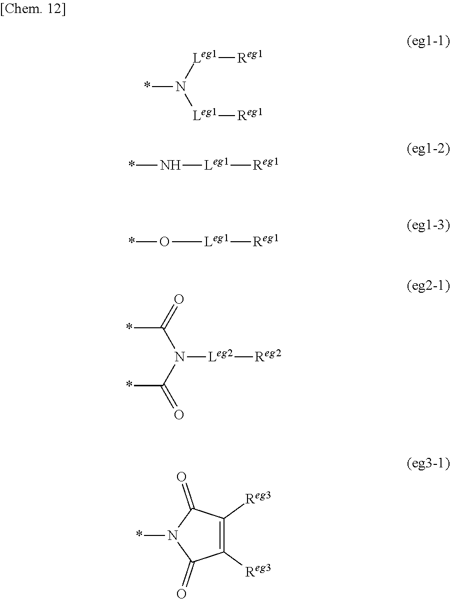

In the formulae, L^{eg1}, R^{eg1}, L^{eg2}, and R^{eg2} have the same meanings as in the formulae (eg1) and (eg2), R^{eg3}'s independently represent a hydrogen atom or an alkyl group having 1 to 5 carbon atoms, and R^{eg3}'s may be bonded to each other to form a ring. In the above formulae, * represents a binding site for a polymer chain, but the group represented by the above formula may sometimes represent not only all or part of a structure (atomic group) derived from a terminal modifier described later introduced at a terminal in the polymer chain using the terminal modifier, but also may sometimes include a structure derived from a monomer that provides each of the structural units described above.

In the polymer (A), a terminal modifier is preferably used in order to introduce a terminal structure as described above. Examples of the terminal modifier include, for example, as the terminal modifier that gives a group represented by the formula (eg1), 4-chloromethylstyrene, 2-hydroxyethyl methacrylate, 2-isocyanatoethyl methacrylate, glycidyl methacrylate, and 3-isopropenylcumyl isocyanate; as the terminal modifier that gives a group represented by the formula (eg2), 4-aminostyrene, 3-aminostyrene, and a combination of two or more modifiers such as tyramine/4-chloromethylstyrene (for example, modification with tyramine and then modification with 4-chloromethylstyrene); and as the terminal modifier that gives a maleimide group, maleic anhydride and citraconic anhydride.

When the terminal modifier is used, the terminal modifier can be added in excess of the absolute value of the difference between the molar amount of the structural unit (a) and the molar amount of the structural unit (b), that is, the molar amount corresponding to the absolute value of the difference between the molar amount of the monomer that gives the structural unit (a) and the molar amount of the monomer that gives the structural unit (b), and the unreacted terminal modifier can be removed by purification after completion of the reaction. Therefore, the addition amount of the terminal modifier is not particularly limited as long as it is in excess of the molar amount corresponding to the absolute value of the difference between the molar amount of the structural unit (a) and the molar amount of the structural unit (b).

### (Characteristics of Polymer (A))

The polymer (A) preferably has a polystyrene equivalent weight average molecular weight (hereinafter also referred to as “Mw”) as measured by gel permeation chromatography (GPC) of about 2,000 to 100,000. When the polymer (A) is used in the photosensitive resin composition, the Mw is more preferably about 2,000 to 50,000, and still more preferably about 3,000 to 30,000. In the case of using the polymer (A) in the photosensitive resin composition, when the Mw is less than 2,000, there is a tendency that sufficient mechanical characteristics as an insulation film cannot be obtained. Meanwhile, when the Mw is more than 100,000, the solubility of the unexposed portion of the photosensitive resin composition obtained using the polymer (A) in a solvent or a developer tends to be poor.

As the polymer (A), one type can be used or two or more types can be used in combination.

A lower limit value of the content ratio of the polymer (A) in 100 mass % of the solid content of the present composition is usually 20 mass %, preferably 40 mass %, and more preferably 60 mass %, and an upper limit value thereof is usually 99 mass % and preferably 95 mass %. Note that the solid content refers to all components other than the solvent (D) described later that can be included in the present composition.

The polymer (A) has at least one type of structure selected from the group consisting of a polyimide and a polyimide precursor. The polyimide precursor includes a polyamic acid and a polyamic acid ester. The structure of the polymer (A) can be checked by, for example, ¹H-NMR.

The polymer (A) is preferably a linear polymer having no branched structure because a patterned resin film having excellent elongation properties can be formed using the present composition. In order to form the polymer (A) into a linear polymer, for example, it is preferable not to use a monomer having a tri- or more functional polymerizable group such as an amino group or an acid anhydride group as a monomer to be used, but to apply only monomers having a bifunctional polymerizable group such as a diamine and an acid dianhydride. As will be described later, since the polymer (A) is synthesized so as to have a polyimide or a polyimide precursor as a repeating unit by a reaction between an acid anhydride and an amine, for example, when the amine to be used has three or more amino groups, the polymer (A) may become a polymer having a branched structure.

### (Method for Producing Polymer (A))

The polymer (A) can be obtained by, for example, causing a reaction in a polymerization solvent to synthesize a polyamic acid using an acid anhydride represented by the formula (1), a diamine (for example, a diamine having a phenolic hydroxy group), and if necessary, an acid anhydride and a diamine other than those described above, and a terminal modifier, and further causing an imidization reaction to synthesize a polyimide. The terminal modifier can be allowed to react before the polyamic acid synthesis, during the polyamic acid synthesis, or after the imidization reaction depending on the introduction site (main chain terminal or side chain terminal). At this time, the polyamic acid synthesized during the process can be the polymer (A) having the polyimide precursor structure described above. In addition, a polyamic acid ester obtained by esterifying a polyamic acid according to a known method can also be the polymer (A) having the polyimide precursor structure described above.

At this time, as a synthesis procedure of a polyamic acid for obtaining a polyimide, for example, the following two types of methods can be applied, and the synthesis may be performed by either method. That is, the methods are (i) a method in which an acid anhydride is dissolved in a polymerization solvent and then a diamine is allowed to react, and (ii) a method in which a diamine is dissolved in a polymerization solvent and then an acid anhydride is allowed to react.

As the polymerization solvent, one that can dissolve raw materials and a product at the time of synthesis of the polymer (A) is selected. As the polymerization solvent, it is preferable to use at least one type selected from the group consisting of N-methyl-2-pyrrolidone, 1,3-dimethyl-2-imidazolidinone, and γ-butyrolactone. These compounds can be used alone as the polymerization solvent, or two or more types thereof can be used in admixture.

In addition to the polymerization solvent, another solvent can be used in combination as needed. Examples of the another solvent include diethylene glycol dialkyl ethers such as diethylene glycol dimethyl ether and diethylene glycol diethyl ether; ethylene glycol monoalkyl ether acetates such as ethylene glycol monomethyl ether acetate; diethylene glycol monoalkyl ether acetates such as diethylene glycol monomethyl ether acetate; propylene glycol monoalkyl ether acetates such as propylene glycol monomethyl ether acetate; ketones such as methyl ethyl ketone and cyclohexanone; alcohols such as methanol, ethanol, and propanol; ether solvents such as diglyme and triglyme; and aromatic hydrocarbons such as toluene and xylene.

As the imidization reaction for obtaining the polymer (A) having a polyimide structure, known methods such as a heating imidization reaction and a chemical imidization reaction can be applied. When the polymer (A) is synthesized by a heating imidization reaction, the polymer (A) is preferably synthesized by heating a synthesis solution of a polyamic acid at 120 to 210° C. for 1 to 16 hours. If necessary, the reaction may be performed while water in the system is removed using an azeotropic solvent such as toluene or xylene.

### <Photopolymerization Initiator (B)>

The present composition includes a photopolymerization initiator (B). The photopolymerization initiator (B) is a compound that generates an active species that promotes a crosslinking reaction between photopolymerizable compounds (C) described later, a crosslinking reaction between polymer terminal groups in the polymer (A), and a crosslinking reaction between the terminal group and a photopolymerizable compound (C) by exposure with visible light, an ultraviolet ray, a far ultraviolet ray, or a radiation such as an electron beam or an X-ray. As the photopolymerization initiator (B), one type may be used or two or more types may be used in combination.

It is considered that the various crosslinking reactions described above are promoted by an exposure treatment of the coating film formed using the present composition, a crosslinked structure is formed in an exposed portion, and the solubility in a developer is reduced.

The photopolymerization initiator (B) is preferably a photosensitive radical polymerization initiator that generates radicals by irradiation with light, and examples thereof include an oxime-based compound, an organic halogenated compound, an oxydiazole compound, a carbonyl compound, a ketal compound, a benzoin compound, an acridine compound, an organic peroxide compound, an azo compound, a coumarin compound, an azide compound, a metallocene compound, a hexaarylbiimidazole compound, an organic boric acid compound, a disulfonic acid compound, an onium salt compound, and an acylphosphine (oxide) compound. Among these, an oxime-based compound, and particularly a photoradical polymerization initiator having an oxime ester structure is preferable from the viewpoint of sensitivity.

The photoradical polymerization initiator having an oxime ester structure may have geometric isomers due to the double bond of the oxime, but these are not distinguished, and both are included in the photopolymerization initiator (B).

Examples of the photoradical polymerization initiator having an oxime ester structure include photoradical polymerization initiators described in WO 2010/146883 A, JP 2011-132215 A, Published Japanese Translation No. 2008-506749 of the PCT International Publication, Published Japanese Translation No. 2009-519904 of the PCT International PublicationJ, and Published Japanese Translation No. 2009-519991 of the PCT International Publication.

Specific examples of the photoradical polymerization initiator having an oxime ester structure include N-benzoyloxy-1-(4-phenylsulfanylphenyl) butan-1-one-2-imine; N-ethoxycarbonyloxy-1-phenylpropan-1-one-2-imine; N-benzoyloxy-1-(4-phenylsulfanylphenyl) octan-1-one-2-imine; N-acetoxy-1-[9-ethyl-6-(2-methylbenzoyl)-9H-carbazol-3-yl]ethane-1-imine; N-acetoxy-1-[9-ethyl-6-{2-methyl-4-(3,3-dimethyl-2,4-dioxacyclopentanylmethyloxy)benzoyl}-9H-carbazol-3-yl]ethane-1-imine; and ethanone, 1-[9-ethyl-6-(2-methylbenzoyl)-9H-carbazol-3-yl]-, 1-(O-acetyloxime).

A lower limit value of the content of the photopolymerization initiator (B) with respect to 100 parts by mass of the polymer (A) in the present composition is usually 0.01 parts by mass, preferably 0.1 parts by mass, and more preferably 0.5 parts by mass, and an upper limit value thereof is usually 30 parts by mass, preferably 20 parts by mass, and more preferably 10 parts by mass. When the content of the photopolymerization initiator (B) is the above lower limit value, curing of the exposed portion becomes sufficient, and the heat resistance of the patterned resin film is easily improved. When the content of the photopolymerization initiator (B) is below the upper limit value, transparency to light used for exposure is not deteriorated, and a patterned resin film having high resolution is easily obtained.

### <Photopolymerizable Compound (C)>

The present composition preferably further includes a photopolymerizable compound (C) for the purpose of, for example, curing the patterned resin film. The photopolymerizable compound (C) is a crosslinking component (curing component) that reacts with a vinyl group, a (meth)acryloyl group, or a maleimide group at a polymer terminal in the polymer (A), and the photopolymerizable compounds (C) can also react with each other. As the photopolymerizable compound (C), one type may be used or two or more types may be used in combination.

Examples of the photopolymerizable compound (C) include a crosslinking agent having at least two (meth)acrylic groups, a crosslinking agent having at least two maleimide groups, a crosslinking agent having at least two styryl groups, and a crosslinking agent having at least two thiol groups. Among these, a crosslinking agent having at least two maleimide groups and a crosslinking agent having at least two styryl groups are preferable.

The crosslinking agent having at least two maleimide groups is a compound having two or more, preferably three or more maleimide groups in the molecule, and an upper limit of the number of maleimide groups is preferably 10, and more preferably 4. The maleimide group is a group that directly acts on the polymer terminal described above, for example, at the time of photocrosslinking or thermal crosslinking, and a cured film formed from the present composition can further exhibit the effect of improving the elongation properties and reliability.

Specific examples of the crosslinking agent having at least two maleimide groups include N,N′-ethylenebismaleimide, N,N′-hexamethylenebismaleimide, N,N′-(2,2,4-trimethylhexane)bismaleimide, N,N′-p-phenylenebismaleimide, N,N′-m-phenylenebismaleimide, N,N′-4-methyl-1,3-phenylenebismaleimide, N,N′-2,4-tolylenebismaleimide, N,N′-2,6-tolylenebismaleimide, N,N′-p-xylylenebismaleimide, N,N′-m-xylylenebismaleimide, N,N′-(1,3-dimethylenecyclohexane)bismaleimide, N,N′-(1,4-dimethylenecyclohexane)bismaleimide, N,N′-(4,4′-biphenylene)bismaleimide, N,N′-(4,4′-diphenylmethane)bismaleimide, N,N′-(3,3′-dimethyl-5,5′-diethyl-4,4′-diphenylmethane)bismaleimide, N,N′-(4,4′-dicyclohexylmethane)bismaleimide, N,N′-(4,4′-diphenyloxy)bismaleimide, N,N′-(4,4′-diphenylsulfone)bismaleimide, bisphenol A diphenyl ether bismaleimide, bis[4-(4-maleimidophenoxy)phenyl]methane, 2,2-bis[4-(4-maleimidophenoxy]phenyl]propane, bis[4-(4-maleimidophenoxy)phenyl]octane, bis[4-(4-maleimidophenoxy)phenyl]decane, bis[4-(4-maleimidophenoxy)phenyl]cyclohexane, and bis[4-(4-maleimidophenoxy)phenyl]-tricyclo-[5.2.1.0^{2.6}]decane.

As the crosslinking agent having at least two maleimide groups, a commercially available product may be used. Examples of the commercially available product of the crosslinking agent having at least two maleimide groups include “BMI-2000”, “BMI-2300”, “BMI-TMH”, “BMI-1000”, “BMI-3000”, “BMI-4000”, “BMI-5100”, and “BMI-7000” manufactured by Daiwa Kasei Industry Co., Ltd.; “MIR-3000” and “MIR-5000” manufactured by Nippon Kayaku Co., Ltd., and “SLK-3000”, “SLK-6895”, “SLK-1500”, “SLK-2500”, and “SLK-6100” manufactured by Shin-Etsu Chemical Co., Ltd.

In addition, a bismaleimide compound in which both terminals of a polyoxyalkylenediamine are blocked with maleic anhydride can also be used. Examples thereof include a bismaleimide compound in which both terminals of a polyoxyalkylenediamine are blocked with maleic anhydride, a bismaleimide compound in which both terminals of a polyoxypropylenediamine are blocked with maleic anhydride, and a bismaleimide compound in which both terminals of a polyoxybutylenediamine are blocked with maleic anhydride.

The crosslinking agent having at least two styryl groups is a compound having two or more, preferably three or more styryl groups in the molecule, and an upper limit of the number of styryl groups is preferably 10, and more preferably 4. The styryl group is a group that directly acts on the polymer terminal described above, for example, at the time of photocrosslinking or thermal crosslinking, and a cured film formed from the present composition can further exhibit the effect of improving the elongation properties and reliability.

Specific examples of the crosslinking agent having at least two styryl groups include divinylbenzene and compounds represented by the following formulae.

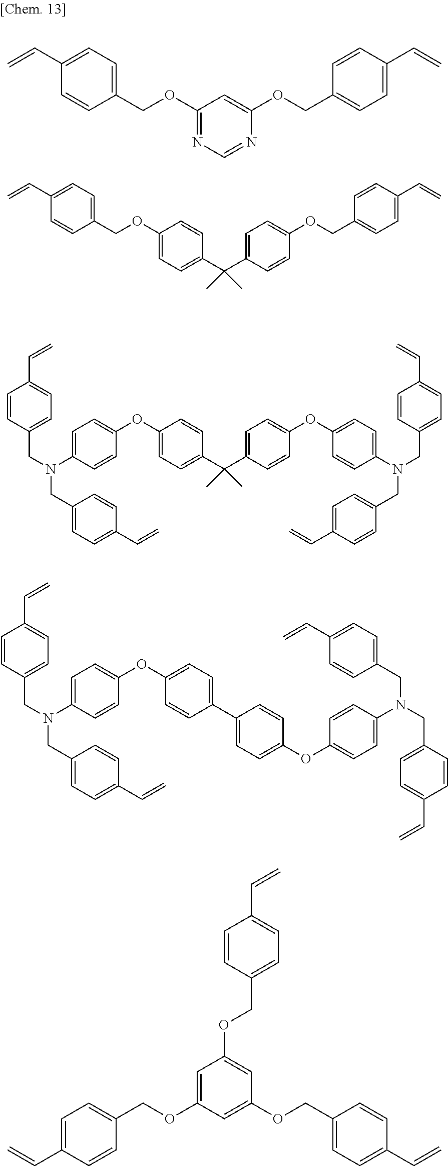

At least one hydrogen atom in the benzene ring in the exemplary compound may be independently substituted with an alkyl group having 1 to 10 carbon atoms. Examples of the alkyl group include a methyl group, an ethyl group, and a propyl group.

As the crosslinking agent having at least two styryl groups, one type may be used or two or more types may be used in combination. The crosslinking agent having at least two styryl groups may be used in combination with a crosslinking agent having at least two maleimide groups. When both are used in combination, the residual film rate (a rate at which the patterned thin film appropriately remains) after development may be improved.

When the present composition includes the photopolymerizable compound (C), the lower limit value of the content of the photopolymerizable compound (C) with respect to 100 parts by mass of the polymer (A) in the present composition is usually 0.1 parts by mass, preferably 1 part by mass, and more preferably 2 parts by mass; and the upper limit value is usually 40 parts by mass, preferably 30 parts by mass, and more preferably 20 parts by mass. When the content of the photopolymerizable compound (C) is equal to or more than the lower limit value or equal to or less than the upper limit value, a patterned resin film having excellent resolution, heat resistance, and elongation properties tends to be formed.

### <Solvent (D)>

The present composition includes a solvent (D). Use of the solvent (D) can improve the handleability of the present composition, and adjust the viscosity and storage stability.

The solvent (D) is not particularly limited as long as it is an organic solvent capable of dissolving or dispersing the respective components such as the polymer (A), the compound (B), and the crosslinking agent (C). Examples of the solvent (D) include a ketone solvent, an alcohol solvent, an ether solvent, an ester solvent, an amide solvent, a hydrocarbon solvent, and a lactone solvent. The solvent (D) preferably contains at least one type selected from the group consisting of a ketone solvent, an amide solvent, and a lactone solvent because of excellent solubility.

Examples of the ketone solvent include cyclic ketone solvents such as cyclohexanone, examples of the amide solvent include cyclic amide solvents such as N-methyl-2-pyrrolidone (NMP) and dimethylimidazolidinone (DMI), and examples of the lactone solvent include cyclic lactone solvents such as γ-butyrolactone (GBL).

As the solvent (D), one type may be used or two or more types may be used in combination.

The content of the solvent (D) in the present composition is such an amount that the solid content concentration in the composition is usually 10 to 50 mass %.

### <Additive (E)>

The present composition can include an additive (E) in addition to the components described above as long as the object and characteristics of the present invention are not impaired. Examples of the additive (E) include a polymer other than the polymer (A), a surfactant, a low molecular weight phenol compound, a silane coupling agent, a rust inhibitor, an adhesion aid, crosslinked fine particles, a leveling agent, a sensitizer, an inorganic filler, and a quencher.

### (Surfactant)

The present composition may include a surfactant from the viewpoint of improving coating properties, defoaming properties, and leveling properties, for example. The surfactant is not particularly limited, and a known nonionic surfactant, fluorine-based surfactant, and silicone-based surfactant can be used.

Examples of a commercially available surfactant include fluorine-based surfactants commercially available under the names such as BM-1000 and BM-1100 (manufactured by BM Chemie), Megafac F142D, Megafac F172, Megafac F173, and Megafac F183 (manufactured by Dainippon Ink & Chemicals Co., Ltd.), Fluorad FC-135, Fluorad FC-170C, Fluorad FC-430, and Fluorad FC-431 (manufactured by Sumitomo 3M Ltd.), Surflon S-112, Surflon S-113, Surflon S-131, Surflon S-141, and Surflon S-145 (manufactured by Asahi Glass Co., Ltd.), SH-28PA, SH-190, SH-193, SZ-6032, and SF-8428 (manufactured by Toray Silicone Co., Ltd.), and NBX-15 (manufactured by Neos Corporation); silicone-based surfactants commercially available under the names such as KL-245 and KL-270 (manufactured by Kyoeisha Chemical Co., Ltd.), and SH28PA (manufactured by Dow Corning Toray Co., Ltd.); and nonionic surfactants commercially available under the names such as NONION S-6, NONION 0-4, PLONON 201, and PLONON 204 (manufactured by NOF CORPORATION), EMULGEN A-60, EMULGEN A-90, and EMULGEN A-500 (manufactured by Kao Corporation), and KL-600 (manufactured by Kyoeisha Chemical Co., Ltd.).

As the surfactant, one type may be used or two or more types may be used in combination. The surfactant is used in a range of an amount of preferably 5 parts by mass or less and more preferably 0.01 to 2 parts by mass with respect to 100 parts by mass of the polymer (A).

### (Adhesion Aid)

The present composition may include an adhesion aid from the viewpoint of improving adhesion to various substrates. The adhesion aid is not particularly limited, and examples thereof include functional silane coupling agents such as a silane coupling agent having a reactive functional group such as a carboxy group, a methacryloyl group, a vinyl group, an isocyanate group, an epoxy group, or an amino group.

As the adhesion aid, one type may be used or two or more types may be used in combination. The adhesion aid is used in a range of an amount of preferably 20 parts by mass or less and more preferably 0.5 to 10 parts by mass with respect to 100 parts by mass of the polymer (A).

### <Method for Producing Photosensitive Resin Composition>

The present composition can be produced by uniformly mixing the respective components constituting the present composition by a known method. In addition, in order to remove foreign matter, after uniformly mixing the respective components, the obtained mixture can be filtered with, for example, a filter.

### [Resin Film Having Pattern]

The resin film having a pattern (patterned resin film) according to an aspect of the present invention is obtained by curing the present composition described above. Specifically, the patterned resin film obtained by the production method described later can be preferably used as an insulation film (examples: a surface protective film, an interlayer insulation film, or a planarization film) included in a semiconductor circuit board.

### [Method for Producing Resin Film Having Pattern]

The patterned resin film can be produced by a method including a step (1) of forming, on a substrate, a coating film of the present composition, a step (2) of selectively exposing the coating film, and a step (3) of developing the coating film after exposure with a developer containing an organic solvent.

### <Step (1)>

In the step (1), the present composition is usually applied onto a substrate so that a thickness of a finally obtained patterned resin film is, for example, 0.1 to 100 μm. The substrate after application of the composition is usually heated at 50 to 140° C. for 10 to 360 seconds using an oven or a hot plate. As such, a coating film formed using the present composition is formed on a substrate.

Examples of the substrate include a silicon wafer, a compound semiconductor wafer, a wafer with a metal thin film, a glass substrate, a quartz substrate, a ceramic substrate, an aluminum substrate, and a substrate having a semiconductor chip on a surface of each of these substrates. Examples of the application method include a dipping method, a spraying method, a bar coating method, a roll coating method, a spin coating method, a curtain coating method, a gravure printing method, a silk screen method, and an inkjet method.

### <Step (2)>

In the step (2), the coating film is selectively exposed using, for example, a contact aligner, a stepper, or a scanner. The expression “selectively” specifically means via a photomask on which a predetermined mask pattern is formed.

Examples of the exposure light include ultraviolet rays and visible rays, and light having a wavelength of 200 to 500 nm (for example, i-line (365 nm)) is usually used. An exposure dose by exposure light varies depending on, for example, the type and blending ratio of each component in the present composition and the thickness of the coating film, and is usually 100 to 1,500 mJ/cm².

In addition, in order to sufficiently perform the crosslinking reaction, it is preferable to perform a heat treatment (post-exposure baking) after exposure. The conditions of the heat treatment after exposure vary depending on, for example, the content of each component in the present composition and the thickness of the coating film, and is usually 70 to 250° C. and preferably 80 to 200° C. for about 1 to 60 minutes.

### <Step (3)>

In the step (3), the coating film after exposure is developed with a developer containing an organic solvent, and an unexposed portion is dissolved and removed to form a desired patterned resin film on the substrate. Examples of the development method include a shower development method, a spray development method, an immersion development method, and a paddle development method. The development conditions are usually 20 to 40° C. and about 1 to 10 minutes. After the resin film is developed with a developer containing an organic solvent, the resin film can be washed with, for example, water or an organic solvent, and dried.

The developer contains one type or two or more types of organic solvents. Examples of the developer include an organic solvent such as a ketone solvent, an alcohol solvent, an ether solvent, an ester solvent, an amide solvent, or a hydrocarbon solvent, and a liquid containing the organic solvent. Among these, at least one type selected from a ketone solvent, an ester solvent, and an amide solvent is preferable. Examples of components other than the organic solvent in the developer include water, silicone oil, and a surfactant.

A content ratio of the organic solvent in the developer is preferably 80 mass % or more, more preferably 90 mass % or more, still more preferably 95 mass % or more, and particularly preferably 99 mass % or more.

The shape of the pattern in the patterned resin film is not particularly limited as long as it has an irregularity structure, and examples thereof include a line-and-space pattern, a dot pattern, a hole pattern, and a lattice pattern.

### <Step (4)>

The method for producing a patterned resin film according to an aspect of the present invention can include, after the step (3), a step (4) of sufficiently curing the patterned resin film by a heat treatment (post-baking), as necessary, in order to sufficiently exhibit characteristics as an insulation film. The curing conditions are not particularly limited, and depending on the application of the patterned resin film, for example, heating is performed at a temperature of 100 to 350° C. for about 30 minutes to 10 hours.

### [Semiconductor Circuit Board]

Use of the present composition enables the production of a semiconductor circuit board including the patterned resin film. The semiconductor circuit board includes a patterned resin film formed using the present composition described above, and preferably includes a patterned insulation film such as a surface protective film, an interlayer insulation film, or a planarization film, and therefore is useful as a highly reliable circuit board.

### EXAMPLES

Hereinafter, the present invention will be described in more detail based on Examples, but the present invention is not limited to these Examples. In the following description of Examples and others, unless otherwise specified, “part(s)” is used to mean “part(s) by mass”.

### <Synthesis of Polymer>

The weight average molecular weight (Mw) of a polymer obtained in the following synthesis example was measured by a gel permeation chromatography (GPC) method under the following conditions.
Column: product name “TSKgel α-M” (manufactured by TOSOH CORPORATION)
Solvent: N-methyl-2-pyrrolidone (NMP)
Temperature: 40° C.
Detection method: refractive index method
Standard substance: polystyrene
GPC apparatus: apparatus name “HLC-8320-GPC” manufactured by TOSOH CORPORATION

### [Synthesis Example 1] Synthesis of Polymer (A1)

In a four-necked flask, 162.23 mmol of BzDAxx (manufactured by ENEOS Corporation, the following formula (a1-1)) as an acid anhydride, 175.39 mmol of 2,2-bis[4-(4-aminophenoxy)phenyl]propane as a diamine, and N-methyl-2-pyrrolidone (NMP) (2.0 g with respect to 1 mmol of the total amount of the acid anhydride and the diamine) as a polymerization solvent were placed. After the inside of the flask was replaced with nitrogen, the contents of the flask were heated at 40° C. for 4 hours and then further heated at 180° C. for 4 hours. After the contents of the flask were cooled to room temperature, 420.94 mmol of 4-(chloromethyl) styrene as a terminal modifier and 420.94 mmol of potassium carbonate as an alkali metal compound were added, and the contents of the flask were heated at 40° C. for 4 hours. After the contents of the flask were cooled to room temperature, the precipitated solid was separated by filtration, methanol was added to the filtrate, the precipitated solid was washed with methanol, and these solids were dried to obtain a polymer (A1). The obtained polymer (A1) was analyzed by, for example, ¹³C-NMR and revealed to be a polymer having a structure represented by the following formula (A1). The obtained polymer (A1) was analyzed by, for example, ¹H-NMR, and it was found that the imidization rate was 100%. The weight average molecular weight (Mw) of the polymer (A1) was 18,000.

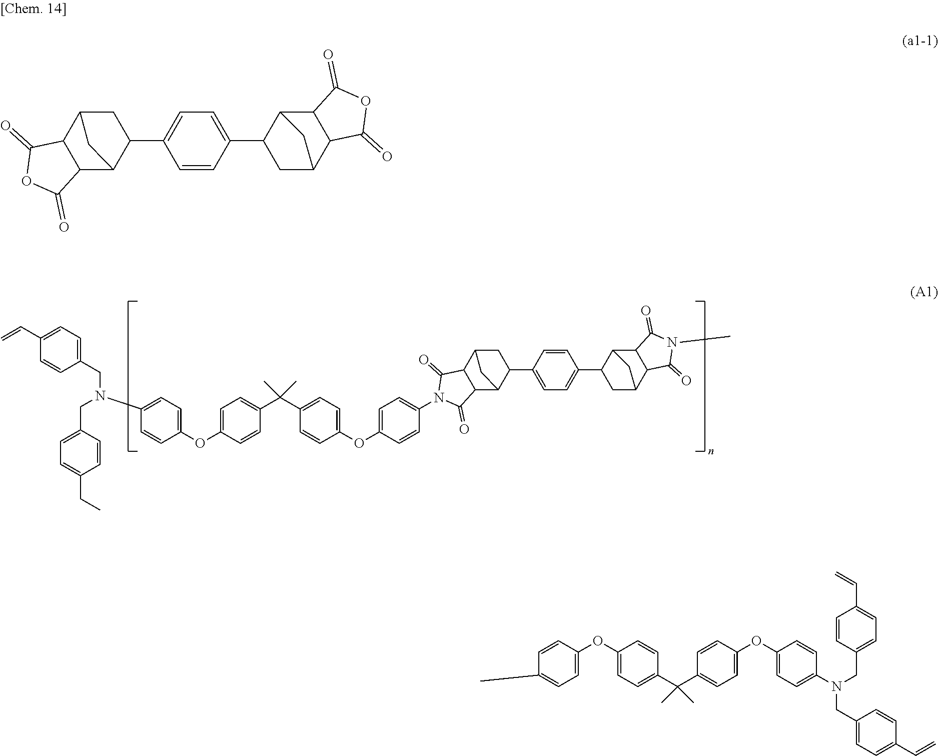

### [Synthesis Example 2] Synthesis of Polymer (A2)

In a four-necked flask, 162.23 mmol of BzDAxx as an acid anhydride, 175.39 mmol of 2,2-bis[4-(4-aminophenoxy)phenyl]propane as a diamine, and NMP (2.0 g with respect to 1 mmol of the total amount of the acid dianhydride and the diamine) as a polymerization solvent were placed. After the inside of the flask was replaced with nitrogen, the contents of the flask were heated at 40° C. for 4 hours and then further heated at 180° C. for 4 hours. After the contents of the flask were cooled to room temperature, 280.62 mmol of maleic anhydride was added as a terminal modifier, and the contents of the flask was heated at 40° C. for 2 hours. After the contents of the flask were cooled to room temperature, 1,052.34 mmol of acetic anhydride and 70.1 mmol of sodium acetate were added, and the contents of the flask was heated at 80° C. for 4 hours. After the contents of the flask were cooled to room temperature, the precipitated solid was separated by filtration, methanol was added to the filtrate, the precipitated solid was washed with methanol, and these solids were dried to obtain a polymer (A2). The obtained polymer (A2) was analyzed by, for example, ¹³C-NMR and revealed to be a polymer having a structure represented by the following formula (A2). The obtained polymer (A2) was analyzed by, for example, ¹H-NMR, and it was found that the imidization rate was 100%. The weight average molecular weight (Mw) of the polymer (A2) was 19,000.

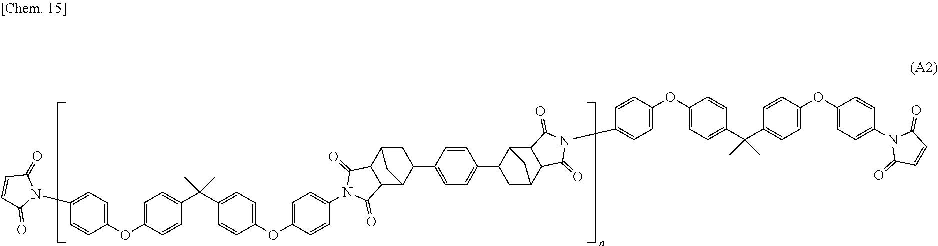

### [Synthesis Example 3] Synthesis of Polymer (A3)

In a four-necked flask, 173.04 mmol of BzDAxx as an acid anhydride, 346.07 mmol of 2-hydroxyethyl methacrylate as a terminal modifier, 346.07 mmol of pyridine as a base, and NMP (2.0 g with respect to 1 mmol of the total amount of the acid dianhydride and the diamine) as a polymerization solvent were placed. After the inside of the flask was replaced with nitrogen, the contents of the flask were heated at 40° C. for 4 hours. After the contents of the flask were cooled to room temperature, 181.69 mmol of 2,2-bis[4-(4-aminophenoxy)phenyl]propane was added as a diamine, and then, under ice cooling, 346.07 mmol of dicyclohexylcarbodiimide (DCC) was added, and the contents of the flask were stirred at room temperature for 4 hours. The precipitated solid was separated by filtration, methanol was added to the filtrate, the precipitated solid was washed with methanol, and these solids were dried to obtain a polymer (A3). The obtained polymer (A3) was analyzed by, for example, ¹³C-NMR and revealed to be a polymer having a structure represented by the following formula (A3). The weight average molecular weight (Mw) of the polymer (A3) was 19,000.

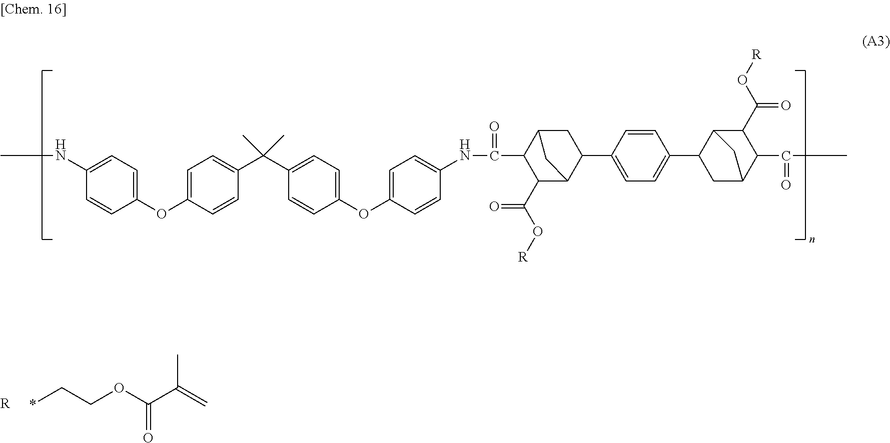

### [Synthesis Example 4] Synthesis of Polymer (A4)

A polymer (A4) was obtained by an operation similar to that in Synthesis Example 1 except that 162.23 mmol of BzDAxx was used as the acid anhydride, 173.64 mmol of 2,2-bis[4-(4-aminophenoxy)phenyl]propane and 1.75 mmol of 1,3-bis(3-aminopropyl)tetramethyldisiloxane were used as the diamines, and 420.94 mmol of 4-(chloromethyl) styrene was used as the terminal modifier in Synthesis Example 1. The obtained polymer (A4) was analyzed by, for example, ¹³C-NMR and revealed to be a polymer (A4) represented by the following formula (A4). The obtained polymer (A4) was analyzed by, for example, ¹H-NMR, and it was found that the imidization rate was 100%. The weight average molecular weight (Mw) of the polymer (A4) was 19,000.

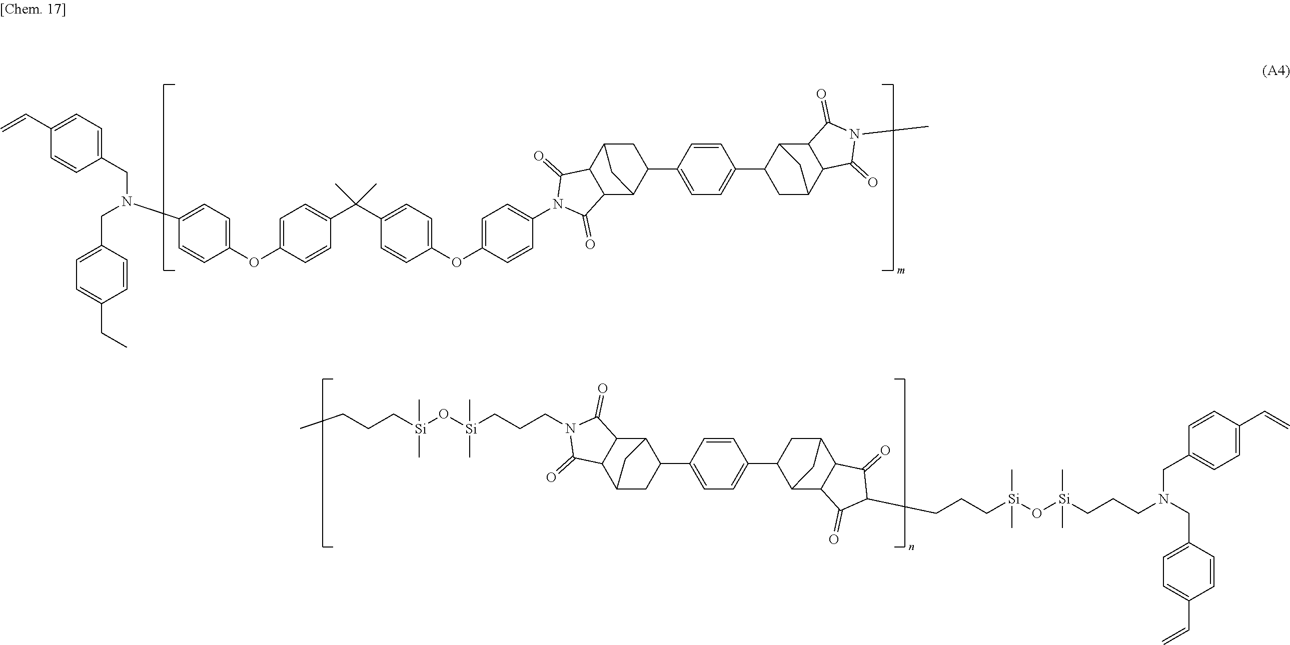

### [Synthesis Example 5] Synthesis of Polymer (A5)

A polymer (A5) was obtained by an operation similar to that in Synthesis Example 1 except that 113.56 mmol of BzDAxx and 48.67 mmol of 4,4′-(4,4′-isopropylidenediphenoxy)bis(phthalic anhydride) were used as the acid anhydrides, 175.39 mmol of 2,2-bis[4-(4-aminophenoxy)phenyl]propane was used as the diamine, and 420.94 mmol of 4-(chloromethyl) styrene was used as the terminal modifier in Synthesis Example 1. The obtained polymer (A5) was analyzed by, for example, ¹³C-NMR and revealed to be a polymer (A5) represented by the following formula (A5). The obtained polymer (A5) was analyzed by, for example, ¹H-NMR, and it was found that the imidization rate was 100%. The weight average molecular weight (Mw) of the polymer (A5) was 20,000.

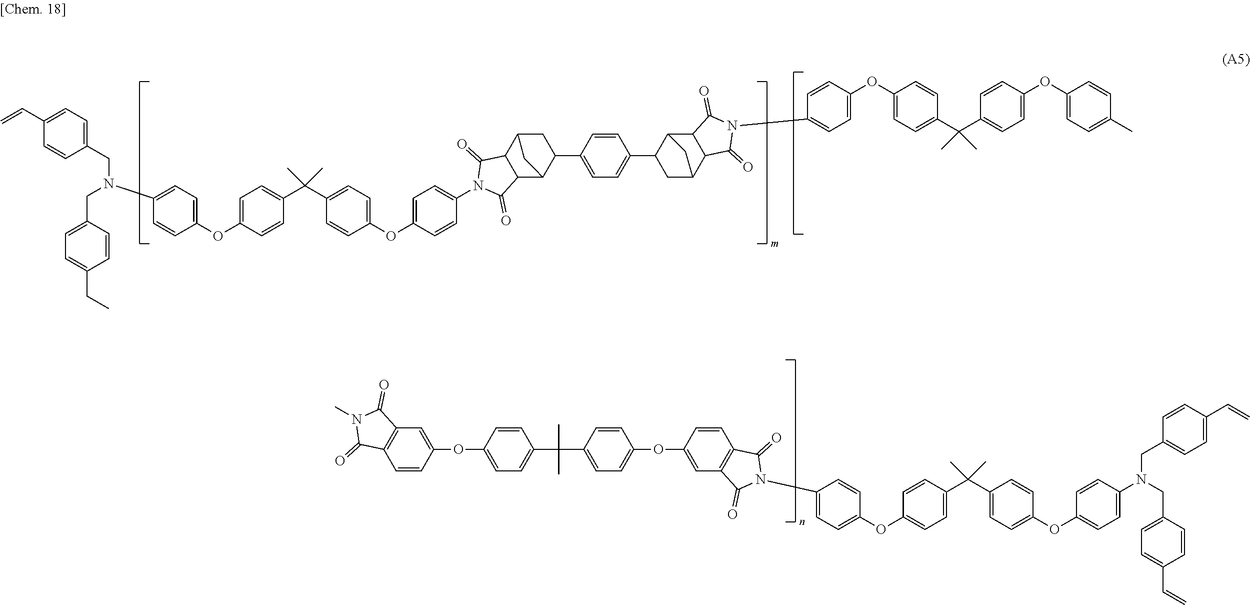

### [Synthesis Example 6] Synthesis of Polymer (A6)

A polymer (A6) was obtained by an operation similar to that in Synthesis Example 1 except that 162.23 mmol of PPHT (manufactured by Nippon Fine Chemical Co., Ltd., the following formula (a1-2)) was used as the acid anhydride in Synthesis Example 1. The obtained polymer (A6) was analyzed by, for example, ¹³C-NMR and revealed to be a polymer (A6) represented by the following formula (A6). The obtained polymer (A6) was analyzed by, for example, ¹H-NMR, and it was found that the imidization rate was 100%. The weight average molecular weight (Mw) of the polymer (A6) was 17,000.

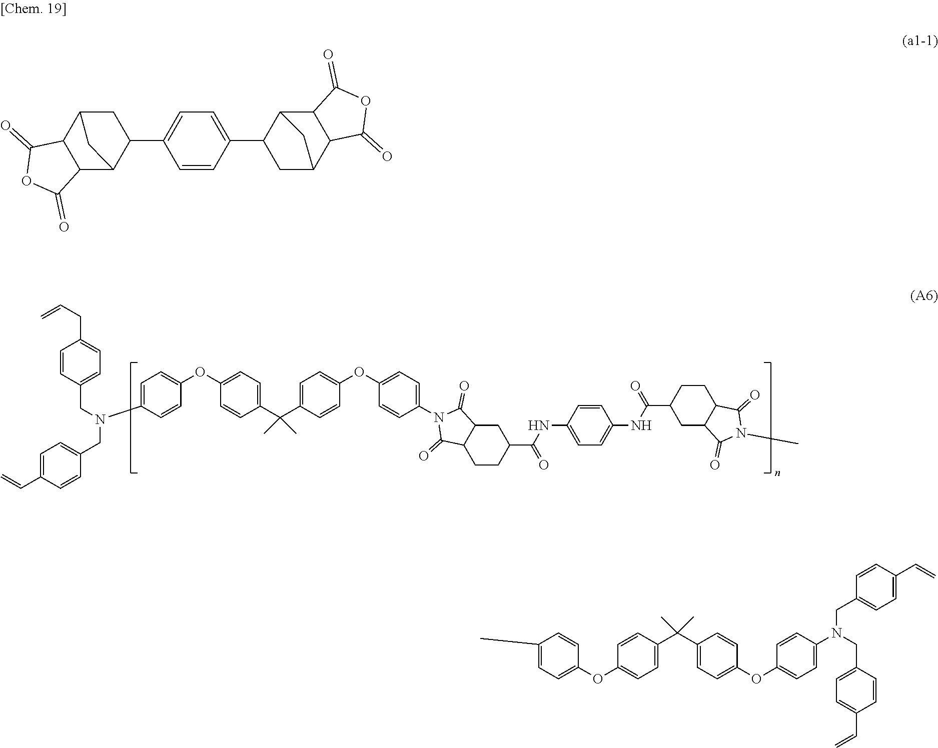

### [Comparative Synthesis Example 1] Synthesis of Polymer (RA1)

In a four-necked flask, 162.23 mmol of 1,2,4,5-cyclohexanetetracarboxylic dianhydride as an acid anhydride, 175.39 mmol of 2,2-bis[4-(4-aminophenoxy)phenyl]propane as a diamine, and NMP (2.0 g with respect to 1 mmol of the total amount of the acid dianhydride and the diamine) as a polymerization solvent were placed. After the inside of the flask was replaced with nitrogen, the contents of the flask were heated at 40° C. for 4 hours and then further heated at 180° C. for 4 hours.

After the contents of the flask were cooled to room temperature, 420.94 mmol of 4-(chloromethyl) styrene as a terminal modifier and 420.94 mmol of potassium carbonate as an alkali metal compound were added, and the contents of the flask were heated at 40° C. for 4 hours. After the contents of the flask were cooled to room temperature, the precipitated solid was separated by filtration, methanol was added to the filtrate, the precipitated solid was washed with methanol, and these solids were dried to obtain a polymer (RA1). The obtained polymer (RA1) was analyzed by, for example, ¹³C-NMR and revealed to be a polymer having a structure represented by the following formula (RA1). The obtained polymer (RA1) was analyzed by, for example, ¹H-NMR, and it was found that the imidization rate was 100%. The weight average molecular weight (Mw) of the polymer (RA1) was 17,000.

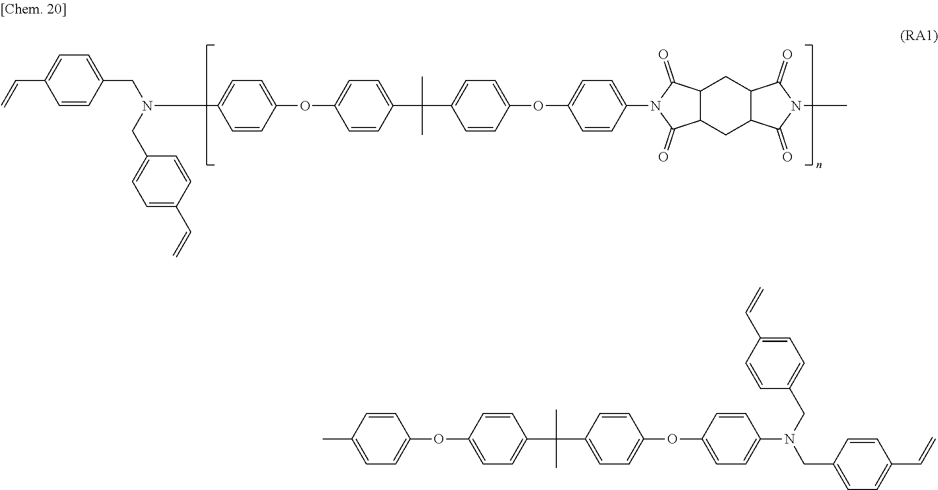

### [Comparative Synthesis Example 2] Synthesis of Polymer (RA2)

In a four-necked flask, 162.23 mmol of 4,4′-(4,4′-isopropylidenediphenoxy)bis(phthalic anhydride) as an acid anhydride, 175.39 mmol of 2,2-bis[4-(4-aminophenoxy)phenyl]propane as a diamine, and NMP (2.0 g with respect to 1 mmol of the total amount of the acid dianhydride and the diamine) as a polymerization solvent were placed. After the inside of the flask was replaced with nitrogen, the contents of the flask were heated at 40° C. for 4 hours and then further heated at 180° C. for 4 hours. After the contents of the flask were cooled to room temperature, 280.62 mmol of maleic anhydride was added as a terminal modifier, and the contents of the flask was heated at 40° C. for 2 hours. After the contents of the flask were cooled to room temperature, 1,052.34 mmol of acetic anhydride and 70.1 mmol of sodium acetate were added, and the contents of the flask was heated at 80° C. for 4 hours. After the contents of the flask were cooled to room temperature, the precipitated solid was separated by filtration, methanol was added to the filtrate, the precipitated solid was washed with methanol, and these solids were dried to obtain a polymer (RA2). The obtained polymer (RA2) was analyzed by, for example, ¹³C-NMR and revealed to be a polymer having a structure represented by the following formula (RA2). The obtained polymer (RA2) was analyzed by, for example, ¹H-NMR, and it was found that the imidization rate was 100%. The weight average molecular weight (Mw) of the polymer (RA2) was 20,000.

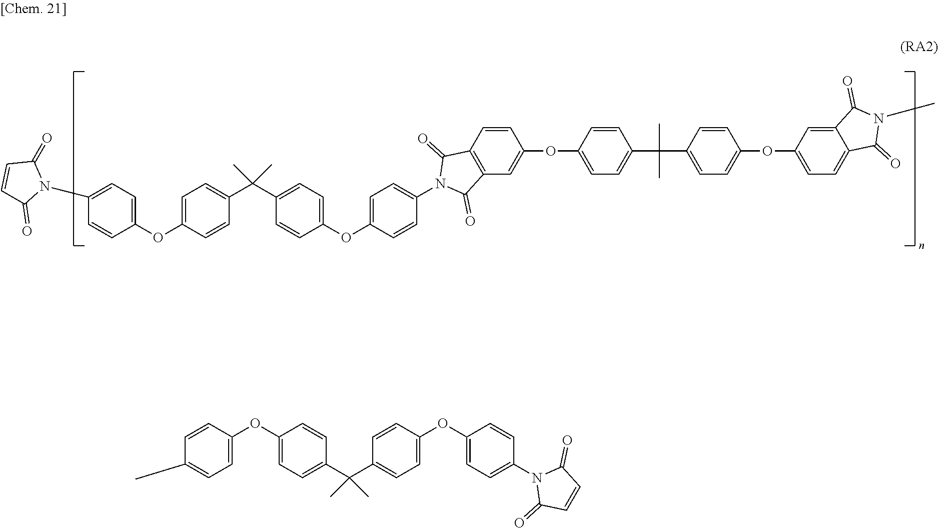

### [Comparative Synthesis Example 3] Synthesis of Polymer (RA3)

In a four-necked flask, 162.23 mmol of BzDAxx as an acid anhydride, 175.39 mmol of 4-[(4-aminophenyl)oxy]-1,3-benzenediamine as an amine, and NMP (2.0 g with respect to 1 mmol of the total amount of the acid anhydride and the amine) as a polymerization solvent were placed. After the inside of the flask was replaced with nitrogen, the contents of the flask were heated at 40° C. for 4 hours and then further heated at 180° C. for 4 hours, and the contents of the flask turned into a gel. This gel-like polymer was used as a polymer (RA3), and the weight average molecular weight (Mw) and imidization rate of the polymer (RA3) were not measured.

### <Synthesis of Photopolymerizable Compound>

### [Synthesis Example 6] Synthesis of Polyfunctional Styryl Compound (C2)

In a four-necked flask, 157.69 mmol of bisphenol A as a phenol compound, 946.17 mmol of 4-(chloromethyl) styrene as a halogen compound, 946.17 mmol of potassium carbonate as an alkali metal compound, and N-methyl-2-pyrrolidone (0.5 g with respect to 1 mmol of the total amount of the halogen compound and the phenol compound) as a synthetic solvent were placed. After the inside of the flask was replaced with nitrogen, the contents of the flask were heated at 80° C. for 4 hours. After the contents of the flask were cooled to room temperature, the precipitated solid was separated by filtration. Methanol was added to the filtrate, and the precipitated solid was dried to obtain a polyfunctional styryl compound (C2) (the following formula). The structure represented by the following formula was checked by analysis of ¹³C-NMR.

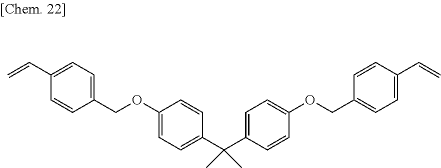 [SMILES: C=Cc1ccc(COc2ccc(C(C)(C)c3ccc(OCc4ccc(C=C)cc4)cc3)cc2)cc1]

The types and amounts of the monomers used in Synthesis Examples 1 to 6 and Comparative Synthesis Examples 1 to 3, and various physical properties of the obtained polymers are shown in the following Table 1.

TABLE 1

| | | Synthesis | Synthesis | Synthesis | Synthesis | Synthesis |
|---|---|---|---|---|---|---|
| | | Example | Example | Example | Example | Example |
| | | 1 | 2 | 3 | 4 | 5 |
| Polymer | | A1 | A2 | A3 | A4 | A5 |
| Acid | a1-1 | 48.1 | 48.1 | 48.8 | 48.1 | 33.6 |
| anhydride | a1-2 | — | — | — | — | — |
| (mol %) | a2-1 | — | — | — | — | — |
| | a2-2 | — | — | — | — | 14.4 |
| Diamine | b-1 | 51.9 | 51.9 | 51.2 | 51.4 | 52.0 |
| (mol %) | b-2 | — | — | — | 0.5 | — |
| Other | b′-1 | — | — | — | — | — |
| amines | | | | | | |
| (mol %) | | | | | | |

| | | | | | |
|---|---|---|---|---|---|
| Terminal | c1 | c2 | c3 | c1 | c1 |
| modifier | | | | | |
| Mw | 18,000 | 19,000 | 19,000 | 19,000 | 20,000 |
| Imidization | 100 | 100 | — | 100 | 100 |
| rate (%) | | | | | |
| Polyimide/ | Polyimide | Polyimide | Polyimide | Polyimide | Polyimide |
| polyimide | | | precursor | | |
| precursor | | | | | |

| | | Synthesis | Comparative | Comparative | Comparative |
|---|---|---|---|---|---|
| | | Example | Synthesis | Synthesis | Synthesis |
| | | 6 | Example 1 | Example 2 | Example 3 |
| Polymer | | A6 | RA1 | RA2 | RA3 |
| Acid | a1-1 | — | — | — | 48.1 |
| anhydride | a1-2 | 48.1 | | | |
| (mol %) | a2-1 | — | 48.1 | — | — |
| | a2-2 | — | — | 48.1 | — |
| Diamine | b-1 | 51.9 | 51.9 | 51.9 | — |
| (mol %) | b-2 | — | — | — | — |
| Other | b′-1 | — | — | — | 51.9 |
| amines | | | | | |
| (mol %) | | | | | |

| | | | | |
|---|---|---|---|---|
| Terminal | c1 | c1 | c2 | — |
| modifier | | | | |
| Mw | 17,000 | 17,000 | 20,000 | Not |
| | | | | measured |
| Imidization | 100 | 100 | 100 | Not |
| rate (%) | | | | measured |
| Polyimide/ | Polyimide | Polyimide | Polyimide | — |
| polyimide | | | | |
| precursor | | | | |

The details of the acid anhydride, the diamine, and the terminal modifier used in Table 1 are shown below.

### Acid Anhydride

(a1-1): BzDAxx (manufactured by ENEOS Corporation)
(a2-1): PPHT (manufactured by Nippon Fine Chemical Co., Ltd.)
(a2-1): 1,2,4,5-Cyclohexanetetracarboxylic dianhydride
(a2-2): 4,4′-(4,4′-Isopropylidenediphenoxy)bis(phthalic anhydride)

### Diamine

(b-1): 2,2-Bis[4-(4-aminophenoxy)phenyl]propane
(b-2): 1,3-Bis(3-aminopropyl)tetramethyldisiloxane

### Other Amines

(b′-1): 4-[(4-aminophenyl)oxy]-1,3-benzenediamine

### Terminal Modifier

(c1): 4-(chloromethyl) styrene
(c2): Maleic anhydride
(c3): 2-Hydroxyethyl methacrylate (HEMA)

### <Production of Photosensitive Resin Composition>

### Examples 1 to 9 and Comparative Examples 1 to 3

The polymer, the photopolymerization initiator, the photopolymerizable compound, and the additive shown in the following Table 2 were uniformly mixed in the amounts shown in Table 2 using the solvent shown in Table 2 so as to have the solid content concentration shown in Table 2, and photosensitive resin compositions of Examples 1 to 9 and Comparative Examples 1 to 3 were produced at the curing temperature and the curing time shown in Table 2. The obtained photosensitive resin compositions were evaluated as follows. The results are shown in Table 2.

### <<Resolution>>

The radiation-sensitive composition was spin-coated on a 6-inch silicon wafer, and then heated at 110° C. for 5 minutes using a hot plate to prepare a coating film (film thickness: 10 μm). Subsequently, the coating film was exposed to an ultraviolet ray from a high-pressure mercury lamp through a photomask of 50×50 μm² square using an aligner (model “MA-150” manufactured by SUSS MicroTec SE) so that the exposure dose at a wavelength of 365 nm was 500 mJ/cm². Then, the film was heated at 150° C. for 3 minutes using a hot plate, and subsequently subjected to immersion development at 23° C. for 3 minutes using a developer (cyclopentanone). The coating film after development was heated in a nitrogen atmosphere under the heating conditions (curing temperature and curing time) shown in Table 2 using an oven to produce a resin film having a pattern. The produced resin film having a pattern was observed with an electron microscope and evaluated according to the following criteria.
O: A pattern could be formed.
X: A pattern cannot be formed.

### <<Tensile Elongation>>

The photosensitive resin composition was applied onto a substrate with a release material, and then, heated at 110° C. for 5 minutes using an oven to prepare a coating film. Subsequently, the entire surface of the coating film was exposed to an ultraviolet ray from a high-pressure mercury lamp using an aligner (model “MA-150” manufactured by Suss MicroTec SE) so that the exposure dose at a wavelength of 365 nm was 500 mJ/cm². Subsequently, the film was heated at 150° C. for 3 minutes using a hot plate, and then heated in a nitrogen atmosphere under the heating conditions (curing temperature and curing time) shown in Table 2 using an oven.

The coating film after heating by post-baking was peeled off from the substrate with a release material to obtain a resin film having a thickness of 15 μm. The obtained resin film was cut into a strip shape of 5 cm long×0.5 cm wide to prepare a tensile test piece. The tensile elongation at break (%) of the strip-shaped resin film was measured by a tensile compression tester (product name “AGS-500NX” manufactured by Shimadzu Corporation). The measurement conditions are as follows: chuck distance=2.5 cm, pulling speed=5 mm/min, and measurement temperature=23° C. The average value of the five measured values was defined as an “elongation (composition)”, and evaluated according to the following criteria.
OO: The elongation was 50% or more.
O: The elongation is 20% or more and less than 50%
X: The elongation was less than 20% or unmeasurable.

### <<PCT Resistance>>

The tensile test piece prepared above was subjected to atmospheric reflow (highest temperature: 260° C.) 3 times, and then exposed to an environment of 130° C./85% RH/96 hr. The tensile elongation of the test piece after exposure was measured in the same manner as in the “elongation (composition)”, and the retention rate of the tensile elongation with respect to the tensile elongation before exposure was evaluated according to the following criteria.
O: The retention rate was 50% or more.
X: The retention rate was less than 50% or unmeasurable.

TABLE 2

| | | Example | Example | Example | Example | Example | Example |
|---|---|---|---|---|---|---|---|
| | | 1 | 2 | 3 | 4 | 5 | 6 |
| Polymer (A) | A1 | 100 | 100 | — | — | — | — |
| (parts by mass) | A2 | — | — | 100 | 100 | — | — |
| | A3 | — | — | — | — | 100 | — |
| | A4 | — | — | — | — | — | 100 |
| | A5 | — | — | — | — | — | — |
| | A6 | — | — | — | — | — | — |
| | RA1 | — | — | — | — | — | — |
| | RA2 | — | — | — | — | — | — |
| | RA3 | — | — | — | — | — | — |
| Photopolymerization | B1 | 3 | 3 | 3 | 3 | 3 | 3 |
| initiator (B) | | | | | | | |
| (parts by mass) | | | | | | | |
| Photopolymerizable | C1 | 15 | — | — | 6 | — | 15 |
| compound (C) | | | | | | | |
| (parts by mass) | C2 | — | 15 | 15 | 15 | — | — |
| Additive (E) | E1 | 0.05 | 0.05 | 0.05 | 0.05 | 0.05 | 0.05 |
| (parts by mass) | E2 | — | — | — | — | — | — |
| Solvent (D) | | D1 | D1 | D1 | D1 | D1 | D1 |
| Solid content concentration | | 34 | 34 | 36 | 36 | 35 | 35 |
| (mass %) | | | | | | | |
| Curing temperature (° C.) | | 230 | 230 | 230 | 230 | 300 | 230 |
| Curing time (h) | | 4 | 4 | 4 | 4 | 1 | 4 |
| Resolution | | ◯ | ◯ | ◯ | ◯ | ◯ | ◯ |
| Tensile elongation | | ◯◯ | ◯◯ | ◯◯ | ◯ | ◯ | ◯◯ |
| PCT resistance | | ◯ | ◯ | ◯ | ◯ | ◯ | ◯ |
| | | Example | Example | Example | Comparative | Comparative | Comparative |
| | | 7 | 8 | 9 | Example 1 | Example 2 | Example 3 |
| Polymer (A) | A1 | — | — | 100 | — | — | — |
| (parts by mass) | A2 | — | — | — | — | — | — |
| | A3 | — | — | — | — | — | — |
| | A4 | — | — | — | — | — | — |
| | A5 | 100 | — | — | — | — | — |
| | A6 | — | 100 | — | — | — | — |
| | RA1 | — | — | — | 100 | — | — |
| | RA2 | — | — | — | — | 100 | — |
| | RA3 | — | — | — | — | — | 100 |
| Photopolymerization | B1 | 3 | 3 | 3 | 3 | 3 | 3 |
| initiator (B) | | | | | | | |
| (parts by mass) | | | | | | | |
| Photopolymerizable | C1 | — | 15 | 15 | 15 | — | 15 |
| compound (C) | | | | | | | |
| (parts by mass) | C2 | 15 | — | — | — | 15 | — |
| Additive (E) | E1 | 0.05 | 0.05 | 0.05 | 0.05 | 0.05 | 0.05 |
| (parts by mass) | E2 | — | — | 5 | — | — | — |

| | | | | | | |
|---|---|---|---|---|---|---|
| Solvent (D) | D1 | D1 | D1 | D1 | D1 | D1 |
| Solid content concentration | 35 | 34 | 34 | 34 | 34 | 34 |
| (mass %) | | | | | | |
| Curing temperature (° C.) | 230 | 230 | 230 | 230 | 230 | 230 |
| Curing time (h) | 4 | 4 | 4 | 4 | 4 | 4 |
| Resolution | ◯ | ◯ | ◯ | ◯ | X | X |
| Tensile elongation | ◯ | ◯◯ | ◯◯ | X | ◯ | X |
| PCT resistance | ◯ | ◯ | ◯ | ◯ | ◯ | X |

The details of the photopolymerization initiator (B), the photopolymerizable compound (C), the additive (E), and the solvent (D) used in Table 2 are shown below.

### Photopolymerization Initiator (B)

(B1): Irgacure OXE02 (ethanone, 1-[9-ethyl-6-(2-methylbenzoyl)-9 H-carbazol-3-yl]-, 1-(O-acetyloxime), manufactured by BASF SE)

### Photopolymerizable Compound (C)

(C1): BMI-2300 (polyfunctional maleimide compound represented by the following formula (C1), manufactured by Daiwa Kasei Industry Co., Ltd.)
(C2): Polyfunctional styryl compound synthesized in Synthesis Example 6

### Additive (E)

(E1): NBX-15 (fluorine-based surfactant, manufactured by Neos Corporation)
(E2): KBM-503 (compound represented by the following formula (E2), manufactured by Shin-Etsu Chemical Co., Ltd.)

### Solvent (D)

(D1): Cyclohexanone

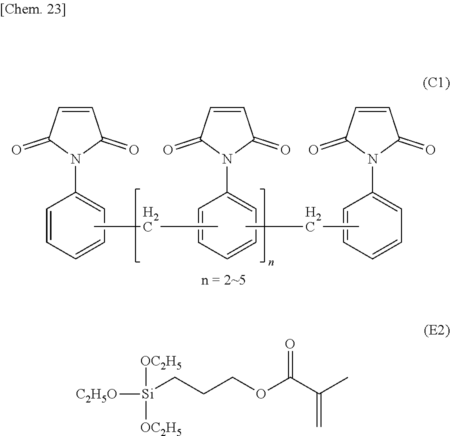

1. A photosensitive resin composition comprising:
(A) a polymer that is at least one selected from the group consisting of a polyimide and a polyimide precursor;
(B) a photopolymerization initiator; and
(D) a solvent, wherein
the polymer (A) comprises a structural unit (a) derived from an acid anhydride and a structural unit (b) derived from a diamine,
the structural unit (a) comprises a structural unit (a1) derived from an acid anhydride represented by formula (1) below, and
the polymer (A) has a group represented by formula (eg1) or (eg2) below or a maleimide group at at least one of a side chain terminal and a main chain terminal: 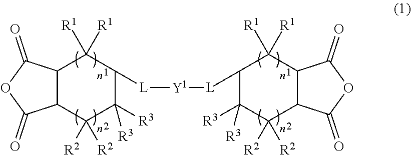
in the formula (1),
L's independently represent a single bond, an ester bond, or an amide bond,
R¹, R², and R³ each independently represent a hydrogen atom or an alkyl group having 1 to 6 carbon atoms, or an alkylene group having 1 to 4 carbon atoms formed by bonding R¹ and R² or R¹ and R³ in a same ring to each other,
n¹ and n² each independently represent an integer of 0 to 3, provided that, in the same ring, at least one of n¹ and n² is an integer of 1 or more,
Y¹ represents a structure represented by formula (Y1) or (Y2) below: 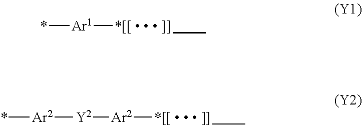
in the formulae (Y1) and (Y2), * represents a bond to L in the formula (1),
Ar¹ and Ar² each independently represent an unsubstituted aromatic ring or a group obtained by removing two hydrogen atoms on an aromatic ring from an aromatic ring substituted with an alkyl group or an alkoxy group having 1 to 6 carbon atoms, and
Y² in the formula (Y2) is at least one group selected from the group consisting of a single bond, an oxygen atom, a sulfur atom, a sulfonyl group, a carbonyl group, a methylene group, a dimethylmethylene group, and a bis(trifluoromethyl)methylene group, and 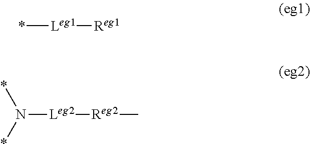
in the formulae (eg1) and (eg2),
L^{eg1} and L^{eg2} each independently represent an alkanediyl group having 1 to 5 carbon atoms, an aromatic hydrocarbon group having 6 to 10 carbon atoms, or a group in which two or more groups selected from the group consisting of an alkanediyl group having 1 to 5 carbon atoms and an aromatic hydrocarbon group having 6 to 10 carbon atom are linked by a single bond, —O—, —S—, —SO₂—, —NH—, —NH—C(O)—, —C(O)—, or —C(O)O—, and
R^{eg1} and R^{eg2} each independently represent a vinyl group or a (meth)acryloyl group, and
* represents a binding site for a polymer chain.

2. The photosensitive resin composition according to claim 1, further comprising a photopolymerizable compound (C).

3. The photosensitive resin composition according to claim 1, wherein the polymer (A) has a group represented by the formula (eg1) or (eg2) or a maleimide group at at least one main chain terminal.

4. The photosensitive resin composition according to claim 3, wherein the polymer (A) is a linear polymer having no branched structure.

5. The photosensitive resin composition according to claim 4, wherein the polymer (A) has a group represented by formula (eg1-1), (eg1-2), (eg1-3), (eg2-1), or (eg3-1) at at least one main chain terminal: 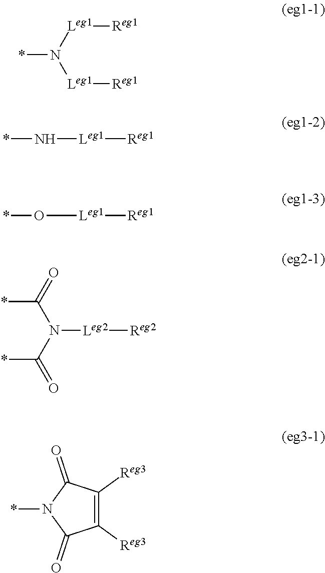
in the formulae,
L^{eg1}, R^{eg1}, L^{eg2}, and R^{eg2} are each as defined in the formulae (eg1) and (eg2),
R^{eg3}'s independently represent a hydrogen atom or an alkyl group having 1 to 5 carbon atoms, or the two R^{eg3}'s taken together represent a ring, and
* represents a binding site for a polymer chain.

6. A method for producing a resin film having a pattern, the method comprising:
forming, on a substrate, a coating film of the photosensitive resin composition according to claim 1;
selectively exposing the coating film; and
developing the coating film after exposure with a developer comprising an organic solvent.

7. A resin film having a pattern obtained by curing the photosensitive resin composition according to claim 1.

8. A semiconductor circuit board comprising the resin film having a pattern according to claim 7.
